(19) United States
(12) Patent Application Publication
(10) Pub. No.: US 2024/0429110 A1
(43) Pub. Date: Dec. 26, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Jangwoo LEE, Suwon-si (KR); Hyunglak MA, Suwon-si (KR); Jiyong PARK, Suwon-si (KR); Jongbo SHIM, Suwon-si (KR)

(21) Appl. No.: 18/667,838

(22) Filed: May 17, 2024

(30) Foreign Application Priority Data
Jun. 20, 2023 (KR) 10-2023-0078817
Sep. 22, 2023 (KR) 10-2023-0127040

(51) Int. Cl. H01L 23/16; H01L 23/31; H01L 23/498; H01L 25/065; H01L 25/10

(52) U.S. Cl. CPC H01L 23/16; H01L 23/3128; H01L 23/49811; H01L 23/49822; H01L 25/0657; H01L 25/105; H01L 2225/06506; H01L 2225/0651; H01L 2225/06562

(57) ABSTRACT

A semiconductor package includes a lower package having opposite first and second lower package sides that extend in a first direction; an upper package stacked on the lower package by conductive connection members, the upper package having opposite first and second upper package sides that extend in the first direction, wherein the second upper package side is spaced apart from the second lower package side by a predetermined distance to define an underfill region on an upper surface of the lower package; and an underfill member extending from the underfill region on the upper surface of the lower package to fill a space between the lower package and the upper package.

### PRIORITY STATEMENT

This application claims priority under 35 U.S.C. § 119 to Korean Patent Application Nos. 10-2023-0078817, filed on Jun. 20, 2023 and 10-2023-0127040, filed on Sep. 22, 2023 in the Korean Intellectual Property Office (KIPO), the disclosures of which are herein incorporated by reference in their entireties.

### BACKGROUND

### 1. Field

Example embodiments relate to a semiconductor package and a method of manufacturing the semiconductor package. More particularly, example embodiments relate to a POP (Package On Package) type semiconductor package in which an upper package is stacked on a lower package and a method of manufacturing the same.

### 2. Description of the Related Art

Due to the increased functionality, speed, and miniaturization of electronic components, such as mobile device components, a method of stacking an upper package on a lower package is utilized as one of the semiconductor packaging technologies. In a package on package (POP) device, the upper package may be mounted on the lower package via conductive connection members such as solder balls. Unfortunately, after the package is mounted on a board, joint cracks of the conductive connection members may occur due to thermal stress, thereby reducing board-level reliability. As such, there is a need to improve the thermal resistance of a processor chip of the lower package.

### SUMMARY

Example embodiments provide a semiconductor package with improved board-level reliability and improved heat dissipation characteristics.

Example embodiments provide a method of manufacturing the semiconductor package.

According to example embodiments, a semiconductor package includes a lower package having opposite first and second lower package sides that extend in a first direction; an upper package stacked on the lower package using conductive connection members, the upper package having opposite first and second upper package sides that extend in the first direction, wherein the first upper package side and the first lower package side are co-planar, and the second upper package side is spaced apart from the second lower package side by a predetermined distance to define an underfill region on an upper surface of the lower package; and an underfill member extending from the underfill region on the upper surface of the lower package to fill a space between the lower package and the upper package.

According to example embodiments, a semiconductor package includes a lower package having a first planar area and opposite first and second lower package sides that extend in a first direction; an upper package stacked on the lower package by conductive connection members, the upper package having a second planar area smaller than the first planar area, the upper package having opposite first and second upper package sides that extends in the first direction, wherein a center of the lower package is offset relative to a center of the upper package, thereby defining an underfill region on an upper surface of the lower package between the second upper package side and the second lower package side; and an underfill member extending from the underfill region on the upper surface of the lower package to fill a space between the lower package and the upper package.

According to example embodiments, a semiconductor package includes a lower package having a first planar area, the lower package having opposite first and second lower package sides that extend in a first direction; an upper package having a second planar area smaller than the first planar area, the upper package having opposite first and second upper package sides that extend in the first direction, wherein a center of the lower package is offset relative to a center of the upper package to define an underfill region on an upper surface of the lower package between the second upper package side and the second lower package side; and an underfill member extending from the underfill region on the upper surface of the lower package and filling a space between the lower package and the upper package. The lower package includes a first package substrate, at least one first semiconductor chip mounted on the first package substrate, conductive connectors on the first package substrate and electrically connected to the at least one first semiconductor chip, a first sealing member on the first package substrate and covering the at least one first semiconductor chip, wherein end portions of the conductive connectors are exposed through the first sealing member, and an interposer electrically connected to the conductive connectors on the first sealing member and having upper connection pads. Each of the conductive connection members is on a respective one of the upper connection pads of the interposer. The first upper package side and the first lower package side are co-planar.

According to example embodiments, a semiconductor package may include a lower package having a first planar area, an upper package stacked on a lower package using conductive connection members and having a second planar area smaller than the first planar area, and an underfill member interposed between the lower package and the upper package. The upper package may be arranged asymmetrically on the lower package to define an underfill region on an upper surface of the lower package.

After mounting the upper package on the lower package at a board level, a liquid underfill member may be dispensed between the lower package and the upper package using the underfill region to form the underfill member. Accordingly, the underfill member may prevent joint cracks of the conductive connection members and serve as a heat dissipation path for heat dissipation of a processor chip of the lower package. Thus, the board level TC reliability of the semiconductor package may be improved and the heat dissipation characteristics may be improved.

### BRIEF DESCRIPTION OF THE DRAWINGS

Example embodiments will be more clearly understood from the following detailed description taken in conjunction with the accompanying drawings. FIGS. 1 to 25 represent non-limiting, example embodiments as described herein.

FIG. 1 is a cross-sectional view illustrating a semiconductor package in accordance with example embodiments.

FIG. 2 is a plan view of FIG. 1.

FIG. 3 is a plan view illustrating a lower package in FIG. 1.

FIGS. 4 to 12 are views illustrating a method of manufacturing a semiconductor package in accordance with example embodiments.

FIG. 13 is a cross-sectional view illustrating a semiconductor package in accordance with example embodiments.

FIG. 14 is an enlarged cross-sectional view illustrating portion ‘D’ in FIG. 13.

FIG. 15 is a plan view illustrating a semiconductor package in accordance with example embodiments.

FIG. 16 is a cross-sectional view illustrating a semiconductor package in accordance with example embodiments.

FIGS. 17 to 25 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings. In all figures in this specification, directions indicated by an arrow and a reverse direction thereto are considered as the same direction.

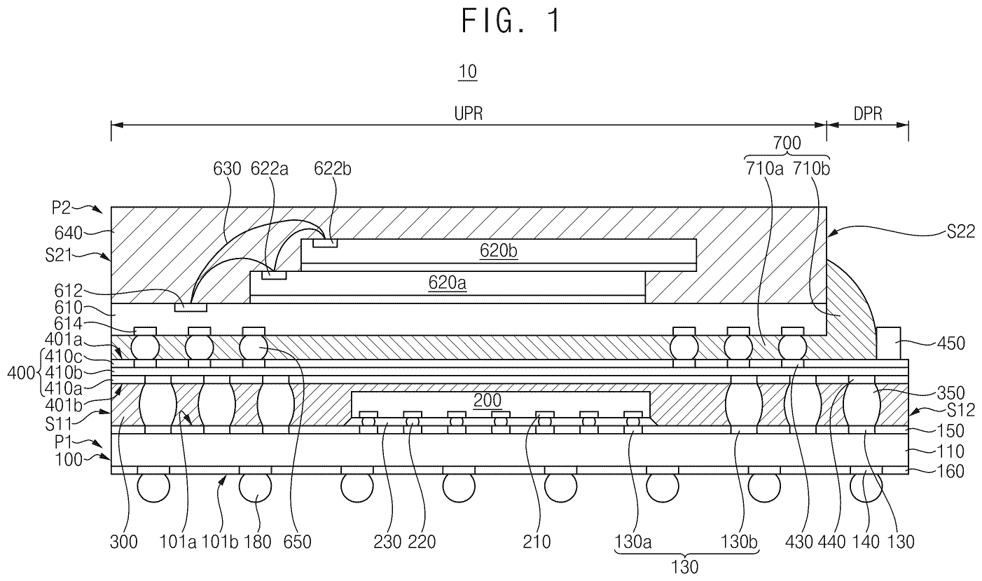

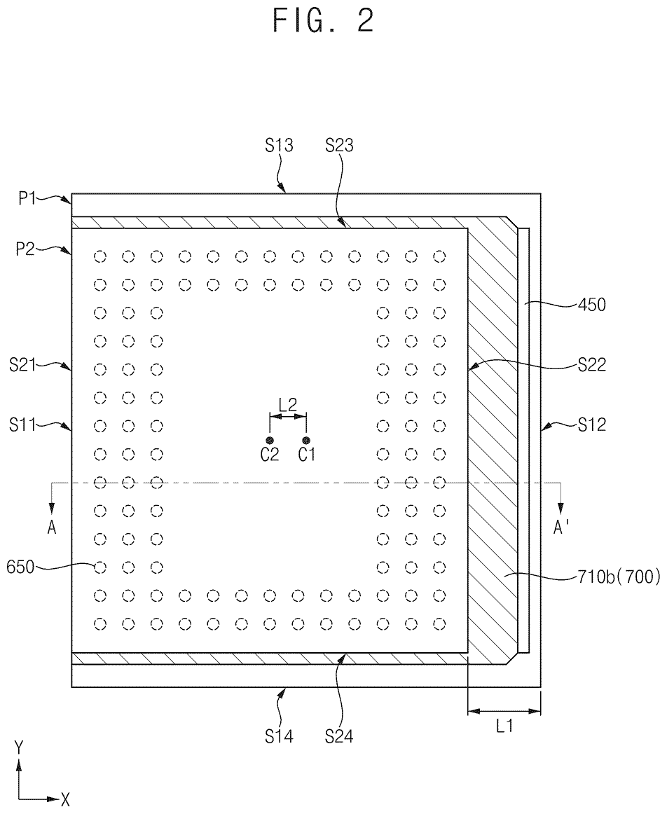

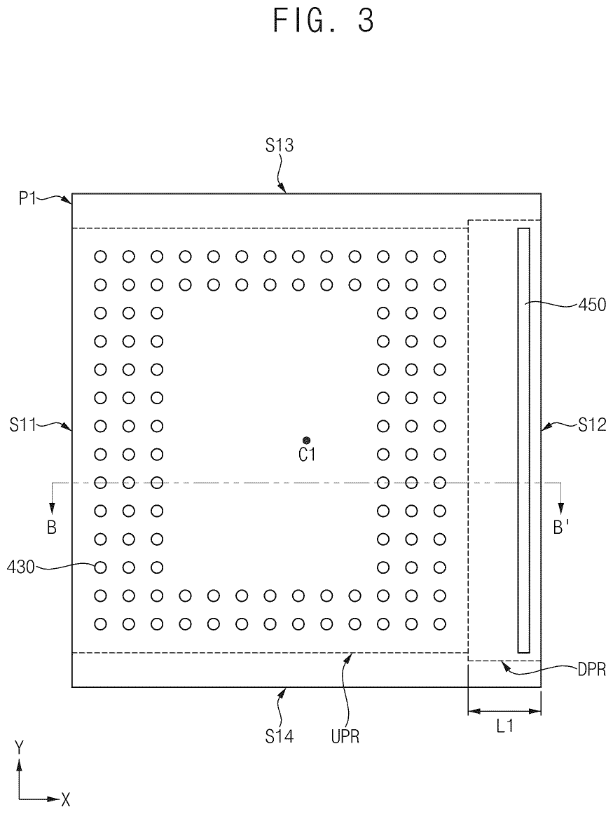

FIG. 1 is a cross-sectional view illustrating a semiconductor package in accordance with example embodiments. FIG. 2 is a plan view of FIG. 1. FIG. 3 is a plan view illustrating a lower package in FIG. 1. FIG. 3 is a plan view illustrating the lower package in FIG. 2, wherein an upper package and conductive connection members are omitted. FIG. 1 includes a cross-sectional portion cut along the line A-A′ in FIG. 2 and a cross-sectional portion cut along the line B-B′ in FIG. 3.

Referring to FIGS. 1 to 3, a semiconductor package 10 may include a lower package P1, an upper package P2 stacked on the lower package P1 using conductive connection members 650, and an underfill member 700 interposed between the lower package P1 and the upper package P2. Additionally, the semiconductor package 10 may further include external connection members 180 provided on a lower surface of the lower package P1.

Additionally, the semiconductor package 10 may be a multi-chip package (MCP) including different types of semiconductor chips. The semiconductor package 10 may be a system in package (SIP) including a plurality of semiconductor chips (for example, a memory chip and a logic chip) that perform multiple functions in one package.

In example embodiments, the lower package P1 may include a first package substrate 100, at least one first semiconductor chip 200 mounted on the first package substrate 100, vertical conductive connectors 350 disposed on the first package substrate 100 and electrically connected to the at least one first semiconductor chip 200, a first sealing member 300 covering the at least one first semiconductor chip 200 and exposing end portions of the vertical conductive connectors 350 (i.e., the end portions of the vertical conductive connectors 350 are not covered by the first sealing member 300), and an interposer 400 on the first sealing member 300 and electrically connected to the vertical conductive connectors 350.

The first package substrate 100 may be a substrate having an upper surface 101a and a lower surface 101b opposite to the upper surface 101a. For example, the first package substrate 100 may include a printed circuit board (PCB), a flexible substrate, a tape substrate, etc. The printed circuit board may be a multilayer circuit board having vias and various circuits therein.

The first package substrate 100 may include a plurality of stacked insulating layers 110 and wirings provided in the insulating layers. Additionally, the first package substrate 100 may include a plurality of upper substrate pads 130 and a plurality of lower substrate pads 140. The wirings may include internal wirings that serve as channels for electrical connection with different types of semiconductor chips.

The upper substrate pads 130 may be exposed from the upper surface 101a (i.e., exposed at the upper surface 101a) of the first package substrate 100, as illustrated in FIG. 1. A first upper insulating layer 150 may be provided on the insulating layers and may expose at least portions of the upper substrate pads 130 (i.e., at least portions of the upper substrate pads 130 are not covered by the first upper insulating layer 150). The lower substrate pads 140 may be exposed from the lower surface 101b (i.e., exposed at the lower surface 101b) of the first package substrate 100. A lower insulating layer 160 may be provided on the insulating layers and may expose at least portions of the lower substrate pads 140 (i.e., at least portions of the lower substrate pads 140 are not covered by the lower insulating layer 160).

In example embodiments, the upper substrate pads 130 may include first substrate pads 130a disposed in a middle region of the first package substrate 100, that is, a chip mounting region, and second substrate pads 130b disposed in an edge region surrounding the chip mounting region. The first substrate pads 130a may be arranged in an array form in the chip mounting region.

The first semiconductor chip 200 may be mounted on the chip mounting region of the first package substrate 100 via conductive bumps 220. The first semiconductor chip 200 may be disposed such that a front surface on which first chip pads 210 are formed, that is, an active surface, faces the first package substrate 100. The first semiconductor chip 200 may have a rectangular shape with four sides when viewed in plan view. The first chip pads 210 may be arranged in an array over the entire front surface of the first semiconductor chip 200.

The first semiconductor chip 200 may be a logic chip including logic circuits. The logic chip may be a controller that controls memory chips. The first semiconductor chip 200 may be a processor chip or an application processor AP such as an ASIC as a host such as CPU, GPU, or SOC.

The first semiconductor chip 200 may be mounted on the first package substrate 100 using a flip chip bonding method. The first chip pads 210 of the first semiconductor chip 200 may be electrically connected to the first substrate pads 130a of the first package substrate 100 through the conductive bumps 220. For example, the conductive bump 220 may include a micro bump (uBump).

Additionally, an underfill member 230 may be underfilled between the first semiconductor chip 200 and the first package substrate 100. The underfill member 230 may include a material with relatively high fluidity to effectively fill a small space between the first semiconductor chip and the first package substrate. For example, the underfill member may include an adhesive containing an epoxy material.

The vertical conductive connectors 350 may be formed on the upper substrate pads 130 of the first package substrate 100, respectively, as illustrated in FIG. 1. The vertical conductive connector 350 may extend in a vertical direction from the upper substrate pad 130 of the first package substrate 100. The vertical conductive connector 350 may include a solder ball. The vertical conductive connectors 350 may be electrically connected to the first semiconductor chip 200 through the wirings of the package substrate 100.

A height of the vertical conductive connector 350 from the upper surface 101a of the first package substrate 100 may be greater than a height of the first semiconductor chip 200 from the upper surface 101a of the first package substrate 100.

The first sealing member 300 may be provided on the first package substrate 100 to cover the first semiconductor chip 200. The first sealing member 300 may fill spaces between the vertical conductive connectors 350, as illustrated in FIG. 1. The first sealing member 300 may expose the end portions of the vertical conductive connectors 350 (i.e., the end portions of the vertical conductive connectors 350 are not covered by the first sealing member 300). The first sealing member 300 may include an epoxy mold compound (EMC).

The interposer 400 may be provided on the first sealing member 300. The interposer 400 may be a silicon interposer or a redistribution wiring interposer having a plurality of wirings formed therein. For example, the interposer 400 may include a plurality of insulating layers 410a, 410b, and 410c and wirings provided in the insulating layers. Upper bonding pads 430 may be exposed from an upper surface 401a (i.e., exposed at the upper surface 401a) of the interposer 400. A third insulating layer 410c may expose at least portions of the upper bonding pads 430 (i.e., at least portions of the upper bonding pads 430 are not covered by the third insulating layer 410c). Lower bonding pads 440 may be exposed from a lower surface 401b (i.e., exposed at the lower surface 401b) of the interposer 400. A first insulating layer 410a may expose at least portions of the lower bonding pads 440 (i.e., at least portions of the lower bonding pads 440 are not covered by the first insulating layer 410a).

The end portions of the vertical conductive connectors 350 exposed by the first sealing member 300 may be bonded to the lower bonding pads 440 of the interposer 400 respectively. The vertical conductive connector 350 may extend in a vertical direction from the upper substrate pad 130 of the first package substrate 100 to the lower bonding pad 440 of the interposer 400.

As illustrated in FIG. 3, the lower package P1 may have a rectangular shape with four sides when viewed in plan view. The lower package P1 may include a first lower package side S11 and a second lower package side S12 extending in a direction parallel to a second direction (Y direction) and perpendicular to the upper surface 401a and facing each other, and may include a third lower package side S13 and a fourth lower package side S14 extending in a direction parallel to a first direction (X direction) perpendicular to the second direction and facing each other. The lower package P1 may have a first planar area. For example, a width of the lower package P1 in the first direction, that is, a distance between the first lower package side S11 and the second lower package side S12, may be 14.1 mm.

An upper surface of the lower package P1, that is, the upper surface 401a of the interposer 400 may include an upper package region UPR and an underfill region DPR. The upper bonding pads 430 of the interposer 400 may be arranged in the upper package region UPR. One side portion of the upper package region UPR may overlap the first lower package side S11. The underfill region DPR may extend along the second lower package side S12 in one side of the upper package region UPR. One side portion of the underfill region DPR may overlap the second lower package side S12. A length L1 of the underfill region DPR in the first direction may be at least 0.5 mm.

In example embodiments, the upper package P2 may be mounted on the lower package P1 via conductive connection members 650.

The upper package P2 may include a second package substrate 610, at least one second semiconductor chip 620a and 620b mounted on an upper surface of the second package substrate 610, second conductive connection members 630 electrically connecting second chip pads 622a and 622b of the at least one second semiconductor chip 620a and 620b to the upper substrate pads 612 on the upper surface of the second package substrate 610, and a second sealing member 640 on the package substrate 610 and covering the at least one second semiconductor chip 620a and 620b, as illustrated in FIG. 1.

A plurality of the second semiconductor chips 620a and 620b may be sequentially stacked on the second package substrate 610 using adhesive members. Bonding wires 630 as the second conductive connection members may connect the second chip pads 622a and 622b of the second semiconductor chips 620a and 620b to the upper substrate pads 612 of the second package substrate 610.

Although the upper package P2 includes two semiconductor chips mounted using a wire bonding method, it will be understood that the number and mounting method of the second semiconductor chips in the upper package may not be limited thereto.

The second semiconductor chips 620a and 620b may include memory chips including memory circuits. For example, the second semiconductor chip may include volatile memory devices such as SRAM devices, DRAM devices, and non-volatile memory devices such as flash memory devices, PRAM devices, MRAM devices, RRAM devices, etc.

The conductive connection members 650 may be interposed between the lower package P1 and the upper package P2 to electrically connect them. A gap may be formed between the upper package P2 and the lower package P1 by the conductive connection members 650. The conductive connection members 650 may be interposed between the upper bonding pads 430 arranged in the upper package region UPR of the lower package P1 and the lower substrate pads 614 of the second package substrate 610 of the upper package P2.

As illustrated in FIG. 2, the upper package P2 may have a rectangular shape with four sides when viewed in plan view. The upper package P2 may include a first upper package side S21 and a second upper package side S21 extending in a direction parallel to the second direction (Y direction) and perpendicular to the upper surface, and facing each other. The upper package P2 may have a second planar area that is smaller than the first planar area. For example, a width of the upper package P2 in the first direction, that is, a distance between the first upper package side S21 and the second upper package side S22, may be 12.4 mm.

The upper package P1 may be arranged asymmetrically on the lower package P2. The upper package P2 may be disposed on the upper package region UPR of the lower package P1. The first upper package side S21 of the upper package P2 may be located on the same plane as the first lower package side S11 of the lower package P1, and the second upper package side S22 may be arranged to be spaced apart from the second lower package side S12 by a predetermined distance L1 such that the upper package P2 defines the underfill region DPR on the upper surface of the lower package P1. A position of the center C2 of the upper package P2 may be shifted in the first direction (−X direction) with respect to the center C1 of the lower package P1 to provide the underfill region DPR between the second upper package side S22 and the second lower package side S12. The center C2 of the upper package P2 may be spaced apart from the center C1 of the lower package P1 by a predetermined second distance L2. For example, the second distance L2 may be smaller than the first distance L1. The second distance L2 may be half of the first distance L1.

In example embodiments, the underfill member 700 may be provided between the lower package P2 and the upper package P1. The underfill member 700 may include a horizontal extension portion 710a that extends in a horizontal direction from the underfill region DPR and fills between the lower package P1 and the upper package P2, and a vertical extension portion 710b that extends in a vertical direction from the underfill region DPR and covers at least a portion of the second upper package side S22 of the upper package P2. For example, the underfill member 700 may include a thermosetting resin such as epoxy resin.

Additionally, the lower package P1 may include a dam structure 450 that extends along one side of the underfill region DPR on the upper surface 401a of the interposer 400. The dam structure 450 may have a predetermined height from the upper surface 401a of the interposer 400. The dam structure 450 may extend within the underfill region DPR on the upper surface of the lower package P1 along the second direction (Y direction) to be adjacent to the second lower package side S12.

The dam structure 450 may contact a portion of an outer surface of the underfill member 700. The dam structure 450 may prevent the underfill member dispensed in the underfill region DPR on the upper surface 401a of the interposer 400 from flowing outward through the second lower package side S12.

In example embodiments, the external connection members 180 for electrical connection with an external device may be disposed on the lower substrate pads 140 on the lower surface 101b of the first package substrate 100. For example, the external connection member 180 may be a solder ball. The semiconductor package 10 may be mounted on a module substrate (not illustrated) using the solder balls to form a semiconductor module.

As mentioned above, the semiconductor package 10 may include the lower package

P1 having the first planar area, the upper package P2 stacked on the lower package P1 via the conductive connection members 650 and having the second planar area smaller than the first planar area, and the underfill member 700 interposed between the lower package P1 and the upper package P2. The upper package P2 may be arranged asymmetrically on the lower package P1. The second upper package side S22 of the upper package P2 may be spaced apart from the second lower package side S12 of the lower package P1 by the predetermined distance L1 to define the underfill region DPR on the upper surface of the lower package P1.

After mounting the upper package P2 on the lower package P1 at the board level, a liquid underfill member may be dispensed between the lower package P1 and the upper package P2 using the underfill region DPR to form the underfill member 700. Accordingly, the underfill member 700 may prevent joint cracks of the conductive connection members 650 and serve as a heat dissipation path for heat dissipation of the processor chip 200 of the lower package P1. Thus, the board level TC reliability of the semiconductor package 10 may be improved and the heat dissipation characteristics may be improved.

Hereinafter, a method of manufacturing the semiconductor package of FIG. 1 will be described.

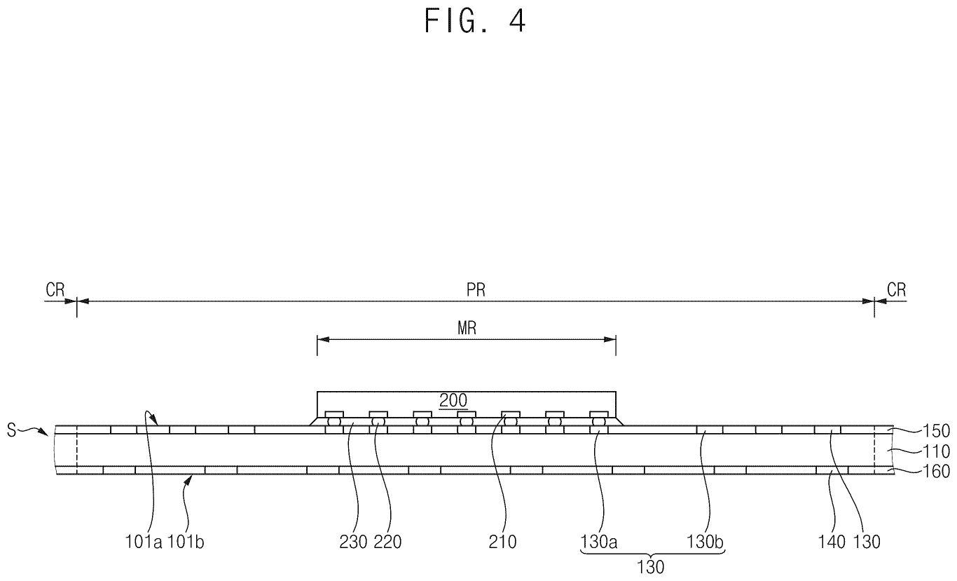

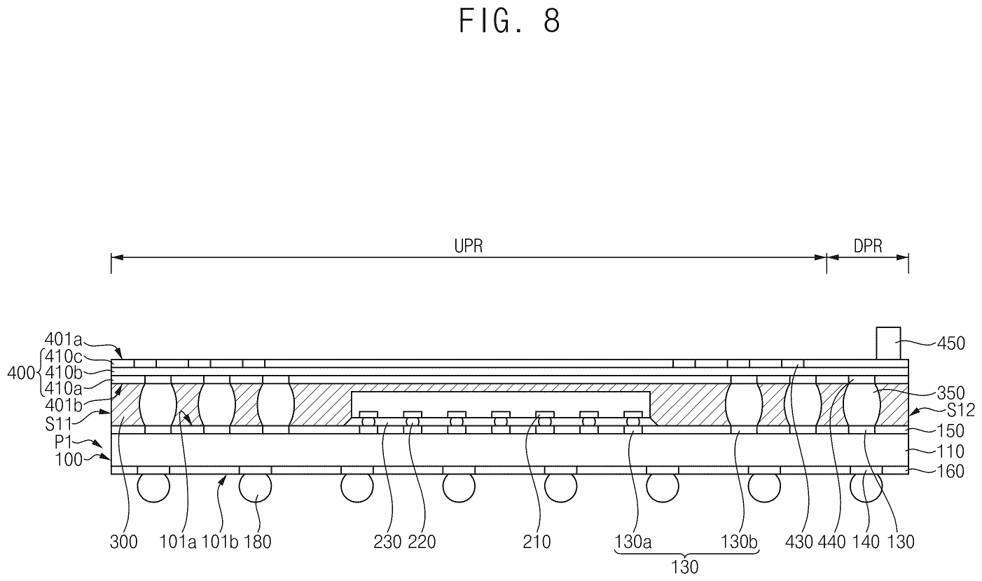

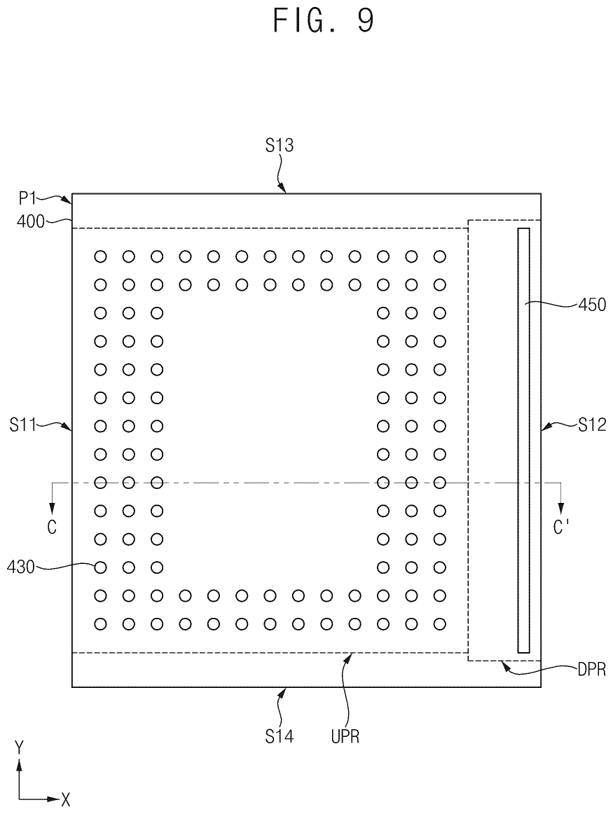

FIGS. 4 to 12 are views illustrating a method of manufacturing a semiconductor package in accordance with example embodiments. FIGS. 4, 5, 6, 7, 8, 10, 11 and 12 are cross-sectional views illustrating a method of manufacturing a semiconductor package in accordance with example embodiments. FIG. 9 is a plan view of FIG. 8. FIG. 8 is a cross-sectional view taken along the C-C′ in FIG. 9.

Referring to FIG. 4, a substrate S in which first package substrates are formed may be provided, and at least one first semiconductor chip 200 may be mounted on the first package substrate.

In example embodiments, the substrate S may be a multilayer circuit board having an upper surface 101a and a lower surface 101b opposite to the first upper surface 101a. The substrate S may be a strip board for manufacturing a semiconductor strip, such as a printed circuit board (PCB). For example, the substrate S may include a printed circuit board (PCB), a flexible board, a tape board, etc. The printed circuit board may be a multilayer circuit board having vias and various circuits therein.

The substrate S may include a package region PR on which a semiconductor chip is mounted and a cutting region CR surrounding the package region PR. As will be described later, after a plurality of semiconductor chips are respectively disposed on the package regions PR of the substrate S, the substrate S may be cut along the cutting region CR that divides the package region PR to be individualized into package substrates.

The substrate S may include a plurality of stacked insulating layers 110 and wirings provided in the insulating layers. Additionally, the substrate S may include a plurality of upper substrate pads 130 and a plurality of lower substrate pads 140. The wirings may include internal wirings that serve as channels for electrical connection with the first semiconductor chip 200.

For example, the insulating layers 110 may include a core layer, a first insulating layer provided on an upper surface of the core layer, and a second insulating layer provided on a lower surface of the core layer. The wirings may include a through via penetrating the core layer, an upper conductive pattern provided on the upper surface of the core layer, and a lower conductive pattern provided on the lower surface of the core layer.

The core layer may include a non-conductive material layer. The core layer may include a reinforcing polymer or the like. The through via may penetrate the core layer and may electrically connect the upper conductive pattern and the lower conductive pattern.

The upper substrate pads 130 may be exposed from the upper surface 101a (i.e., the upper substrate pads 130 may be exposed at the upper surface 101a) of the substrate S. The upper substrate pads 130 may be provided on the first insulating layer and may be electrically connected to the upper conductive pattern. A first upper insulating layer 150 may be provided on the first insulating layer 150 and may expose at least portions of the upper substrate pads 130 (i.e., at least portions of the upper substrate pads 130 are not covered by the first upper insulating layer 150).

The lower substrate pads 140 may be exposed from the lower surface 101b (i.e., the lower substrate pads 140 may be exposed at the lower surface 101b) of the substrate 100. The lower substrate pads 134 may be provided on the second insulating layer and may be electrically connected to the lower conductive pattern. A lower insulating layer 160 may be provided on the second insulating layer and may expose at least portions of the lower substrate pads 140 (i.e., at least portions of the lower substrate pads 140 are not covered by the lower insulating layer 160).

For example, the first and second insulating layers may include an insulating material. Examples of the insulating material may be a thermosetting resin such as epoxy resin or a thermoplastic resin such as polyimide. The first and second insulating layers may include a resin impregnated in a core material such as organic fiber (glass fiber), for example, prepreg, FR-4, BT (Bismaleimide Triazine), etc. The upper insulating layer and the lower insulating layer may include solder resist, etc.

In example embodiments, the upper substrate pads 130 may include first substrate pads 130a disposed in a middle region, that is, a chip mounting region MR of the package region PR, and second substrate pads 130b disposed in an edge region surrounding the chip mounting region. The first substrate pads 130a may be arranged in an array form in the chip mounting region.

Then, the at least one first semiconductor chip 200 may be mounted on the package region PR of the substrate S.

In example embodiments, the first semiconductor chip 200 may be mounted on the chip mounting region MR of the substrate S via conductive bumps 220. The first semiconductor chip 200 may be disposed such that a front surface 202 on which first chip pads 210 are formed, that is, an active surface, faces the substrate S. The first semiconductor chip 200 may have a rectangular shape with four sides when viewed in plan view. The first chip pads 210 may be arranged in an array over the entire front surface 202 of the first semiconductor chip 200.

The first semiconductor chip 200 may be a logic chip including logic circuits. The logic chip may be a controller that controls memory chips. The first semiconductor chip may be a processor chip such as ASIC or an application processor AP as a host such as CPU, GPU, or SOC.

The first semiconductor chip 200 may be mounted on the substrate S using a flip chip bonding method. The first chip pads 210 of the first semiconductor chip 200 may be electrically connected to the first substrate pads 130a of the substrate S through the conductive bumps 220. For example, the conductive bump 220 may include a micro bump (uBump). A thickness of the first semiconductor chip 200 may be within a range of 40 μm to 110 μm.

Additionally, an underfill member 230 may fill a space between the first semiconductor chip 200 and the substrate S. The underfill member may include a material with relatively high fluidity to effectively fill a small space between the first semiconductor chip and the substrate. For example, the underfill member may include an adhesive containing an epoxy material.

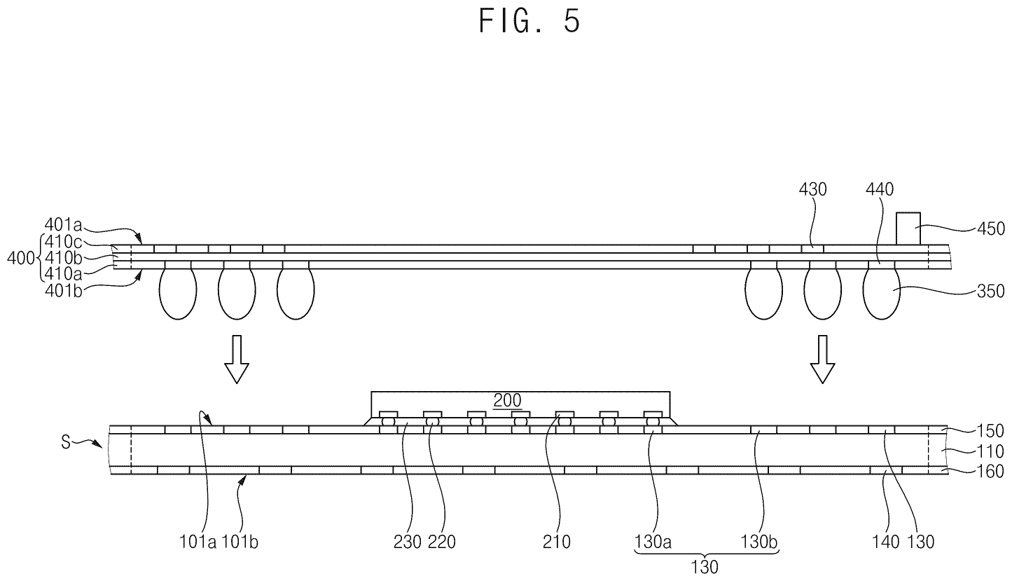

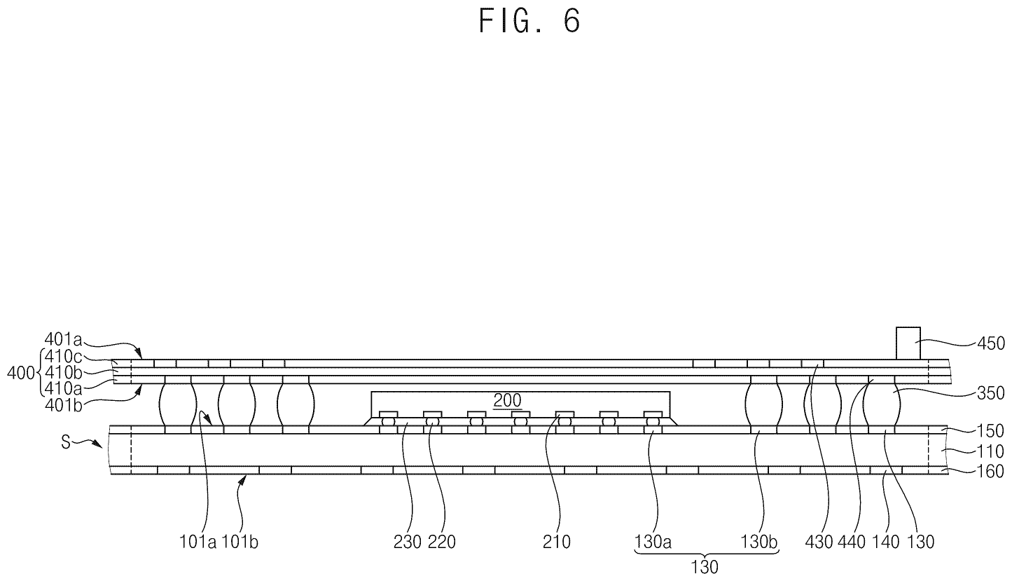

Referring to FIGS. 5 and 6, an interposer 400 may be disposed on the substrate S via vertical conductive connectors 350.

As illustrated in FIG. 5, the vertical conductive connectors 350 may be formed on lower bonding pads 440 on a lower surface 401b of the interposer 400, and the interposer 400 is placed on the substrate S such that the vertical conductive connectors 350 face the substrate S.

The interposer 400 may be a silicon interposer or a redistribution wiring interposer having a plurality of wirings formed therein. For example, the interposer 400 may include a plurality of insulating layers 410a, 410b, and 410c and the wirings provided in the insulating layers. Upper bonding pads 430 may be exposed from an upper surface 401a (i.e., upper bonding pads 430 may be exposed at an upper surface 401a) of the interposer 400. A third insulating layer 410c may expose at least portions of the upper bonding pads 430 (i.e., at least portions of the upper bonding pads 430 are not covered by the third insulating layer 410c). The lower bonding pads 440 may be exposed from the lower surface 401b (i.e., the lower bonding pads 440 may be exposed at the lower surface 401b) of the interposer 400. A first insulating layer 410a may expose at least portions of the lower bonding pads 440 (i.e., at least portions of the lower bonding pads 440 are not covered by the first insulating layer 410a).

The vertical conductive connectors 350 may be formed on the lower bonding pads 440, respectively. The vertical conductive connector 350 may extend in a vertical direction from the lower bonding pad 440. The vertical conductive connector 350 may include a solder ball.

In example embodiments, the interposer 400 may include a dam structure 450 that extends along one side of the cutting region CR on the upper surface 401a of the interposer 400. The dam structure 450 may have a predetermined height from the upper surface 401a of the interposer 400. As will be described later, the dam structure 450 may prevent an underfill member dispensed on the upper surface 401a of the interposer 400 from flowing out.

As illustrated in FIG. 6, the vertical conductive connectors 350 may be respectively placed on the second substrate pads 130b of the substrate S by a solder ball attach process. The vertical conductive connectors 350 on the interposer 400 may be thermally compressed on the upper surface 101a of the substrate S. The vertical conductive connectors 350 may be bonded to the second substrate pads 130b through a reflow process. The vertical conductive connectors 350 may be electrically connected to the first semiconductor chip 200 through the wirings of the substrate S.

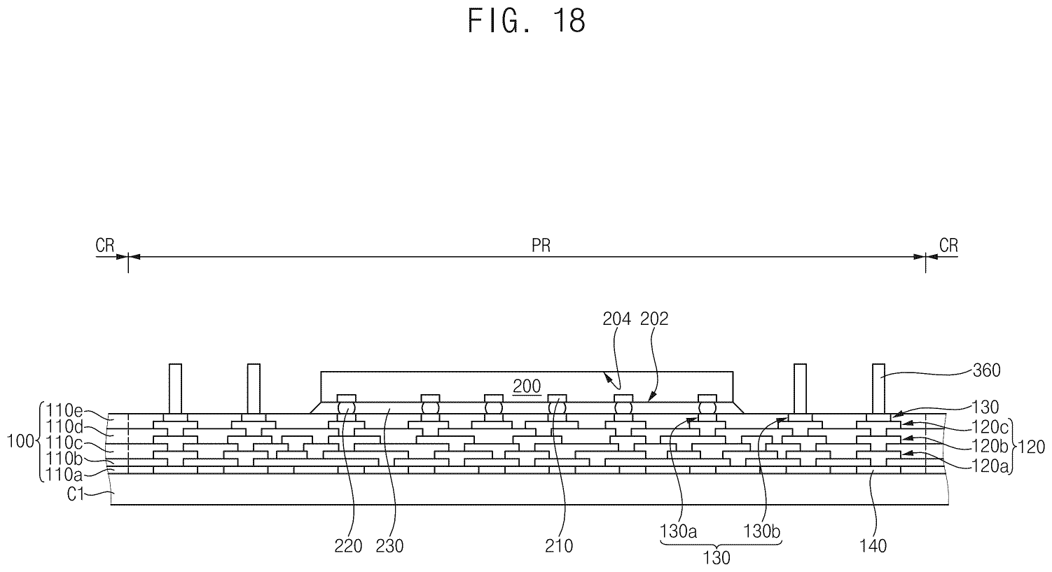

A height of the vertical conductive connectors 350 from the upper surface 101a of the substrate S may be greater than a height of the first semiconductor chip 200 from the upper surface 101a of the substrate S. Accordingly, the interposer 400 may be supported on the substrate S by the vertical conductive connectors 350, and the lower surface 401b of the interposer 400 may be spaced apart from the upper surface 101a of the substrate S and a backside surface 204 (FIG. 18) of the first semiconductor chip 200 to form a space between the substrate S and the interposer 400.

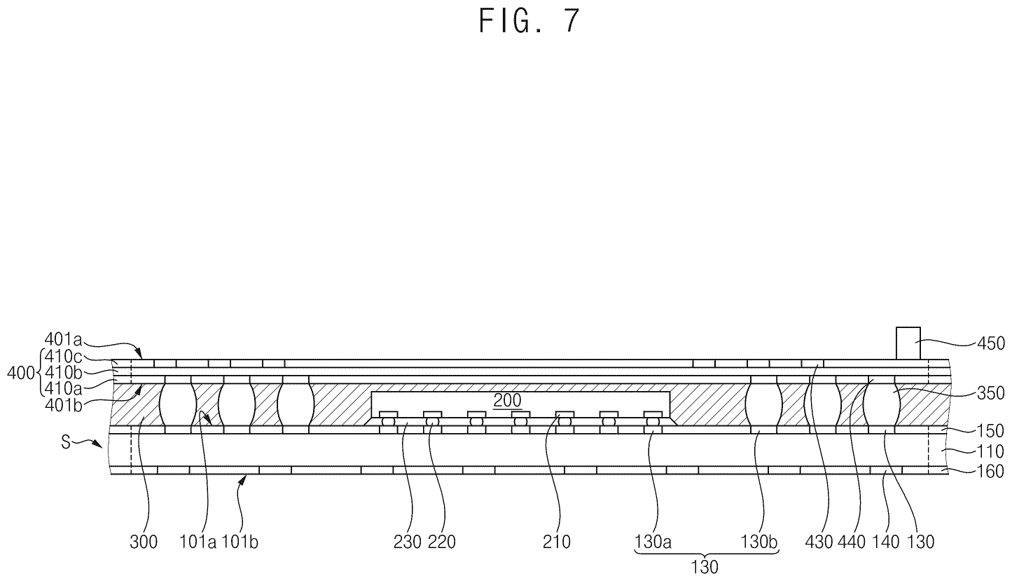

Referring to FIG. 7, a first sealing member 300 may be formed on the substrate S to cover the first semiconductor chip 200.

For example, a molding material may be injected into the space between the substrate S and the interposer 400 by a transfer molding process to form the first sealing member 300 covering the first semiconductor chip 200. The first sealing member 300 may fill spaces between the vertical conductive connectors 350. The first sealing member 300 may include an epoxy mold compound EMC. The first sealing member 300 may include UV resin, polyurethane resin, silicone resin, silica fillers, etc.

Referring to FIGS. 8 and 9, external connection members 180 may be disposed on the lower substrate pads 140 on the lower surface 101b of the substrate S, and the substrate S may be diced to form individual lower packages P1.

In example embodiments, solder balls as the external connection members may be disposed on the lower substrate pads 140 on the lower surface 101b of the substrate S. Then, the substrate S may be cut along the cutting region CR dividing the plurality of package regions PR by a sawing process to be individualized into a plurality of the lower packages P1.

The lower package P1 may include a first package substrate 100, the at least one first semiconductor chip 200 mounted on the first package substrate 100, the vertical conductive connectors 350 on the first package substrate 100 and electrically connected to the first semiconductor chip 200, the first sealing member 300 on the first package substrate 100, covering the at least one first semiconductor chip 200 and exposing end portions of the vertical conductive connectors 350 (i.e., end portions of the vertical conductive connectors 350 are not covered by the first sealing member 300), and the interposer 400 on the first sealing member 300 and electrically connected to the vertical conductive connectors 350.

As illustrated in FIG. 9, the lower package P1 may have a rectangular shape with four sides when viewed in plan view. The lower package P1 may include a first lower package side S11 and a second lower package side S12 extending in a direction parallel to a second direction (Y direction) and perpendicular to the upper surface 401a and facing each other, and may include a third lower package side S13 and a fourth lower package side S14 extending in a direction parallel to a first direction (X direction) perpendicular to the second direction and facing each other. The lower package P1 may have a first planar area. For example, a width of the lower package P1 in the first direction, that is, a distance between the first lower package side S11 and the second lower package side S12, may be 14.1 mm.

The lower package P1 may include an upper package region UPR and an underfill region DPR on the upper surface 401a of the interposer 400. The upper bonding pads 430 of the interposer 400 may be arranged in the upper package region UPR. One side portion of the upper package region UPR may overlap the first lower package side S11. The underfill region DPR may extend along the second lower package side S12 in one side of the upper package region UPR. One side portion of the underfill region DPR may overlap the second lower package side S12. A length L1 of the underfill region DPR in the first direction may be at least 0.5 mm.

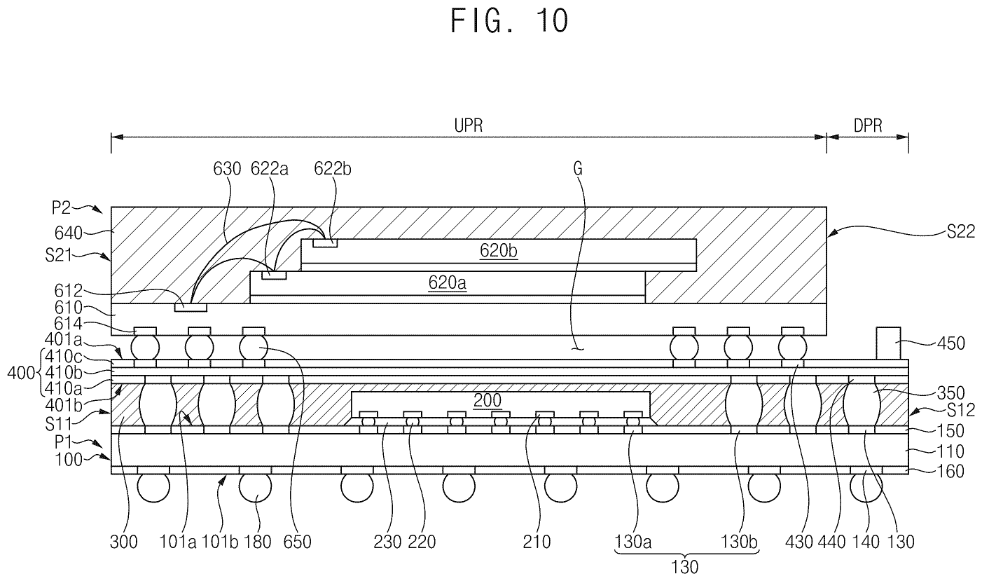

Referring to FIG. 10, an upper package P2 may be stacked on the lower package P1 via conductive connection members 650.

In example embodiments, the upper package P2 may include a second package substrate 610, at least one second semiconductor chip 620a, 620b mounted on an upper surface of the second package substrate 610, second conductive connection members electrically connecting second chip pads 622a and 622b of the at least one second semiconductor chip 620a and 620b to upper substrate pads 612 on the upper surface of the second package substrate 610, and a second sealing member 640 covering the at least one second semiconductor chip 620a and 620b on the second package substrate 610.

A plurality of the second semiconductor chips 620a and 620b may be sequentially stacked on the second package substrate 610 using adhesive members. Bonding wires 630 as the second conductive connection members may connect the second chip pads 622a and 622b of the second semiconductor chips 620a and 620b to the upper substrate pads 612 of the second package substrate 610.

Although the upper package P2 includes two semiconductor chips mounted using a wire bonding method, it will be understood that the number and mounting method of the second semiconductor chips in the upper package may not be limited thereto.

The second semiconductor chips 620a and 620b may include memory chips including memory circuits. For example, the second semiconductor chip may include volatile memory devices such as SRAM devices or DRAM devices, and non-volatile memory devices such as flash memory devices, PRAM devices, MRAM devices or RRAM devices.

In example embodiments, solder balls as the conductive connection members may be respectively formed on lower substrate pads 614 of a lower surface of the package substrate 610 of the upper package P2 by a solder ball attach process, and then, the upper package P2 may be mounted on the lower package P1 via the conductive connection members.

The conductive connection members 650 may be interposed between the lower package P1 and the upper package P2 to electrically connect them. A gap G may be formed between the upper package P2 and the lower package P1 by the conductive connection members 650. The conductive connection members 650 formed on the lower substrate pads 614 of the second package substrate 610 of the lower package P1 may be bonded to the upper bonding pads 430 arranged in the upper package region UPR of the interposer 400.

The upper package P2 may have a rectangular shape with four sides when viewed in plan view. The upper package P2 may include a first upper package side S21 and a second upper package side S22 extending in a direction parallel to the second direction (Y direction) and perpendicular to the upper surface, and facing each other. The upper package P2 may have a second planar area that is smaller than the first planar area. For example, a width of the upper package P2 in the first direction, that is, a distance between the first upper package side S21 and the second upper package side S22, may be 12.4 mm.

The upper package P2 may be disposed on the upper package region UPR of the lower package P1. The first upper package side S21 of the upper package P2 may be located on the same plane as the first lower package side S11 of the lower package P1 (i.e., the first upper package side S21 of the upper package P2 and the first lower package side S11 of the lower package P1 may be co-planar), and the second upper package side S22 may be arranged to be spaced apart from the second lower package side S12 by a predetermined distance L1 such that the upper package P2 exposes the underfill region DPR on the upper surface of the lower package P1. A position of the center of the upper package P2 may be shifted in the first direction (−X direction) with respect to the center C1 of the lower package P1 to provide the underfill region DPR between the second upper package side S22 and the second lower package side S12.

In this case, the dam structure 450 may extend along the second direction (Y direction) to be adjacent to the second lower package side S12 within the underfill region DPR on the upper surface of the lower package P1.

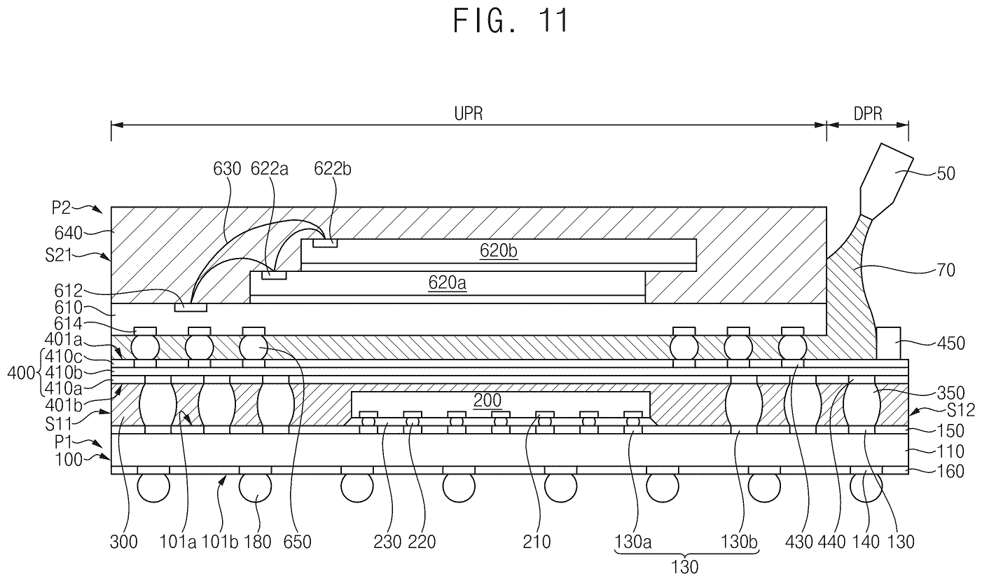

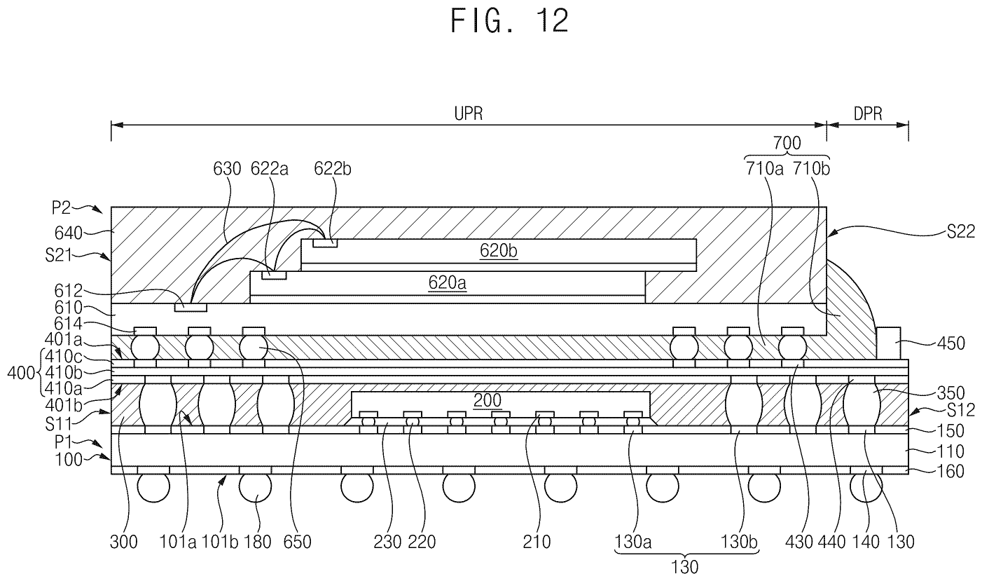

Referring to FIGS. 11 and 12, an underfill member 700 may be formed between the lower package P1 and the upper package P2.

As illustrated in FIG. 11, while moving a dispenser nozzle 50 in the second direction (Y direction) along the underfill region DPR between the second upper package side S22 and the second lower package side S12, a liquid underfill aqueous solution 70 may be dispensed into the gap G between the lower package P2 and the upper package P1. For example, the aqueous underfill solution may include an epoxy material. The underfill aqueous solution may flow from the underfill region DPR to the gap G between the lower package P1 and the upper package P2 and then harden to form the underfill member 700.

At this time, the dam structure 450 may prevent the underfill aqueous solution 70 dispensed in the underfill region DPR on the upper surface 401a of the interposer 400 from flowing outward through the second lower package side S12.

As illustrated in FIG. 12, the underfill member 700 may include a horizontal extension portion 710a that extends in a horizontal direction from the underfill region DPR and fills between the lower package P1 and the upper package P2, and a vertical extension portion 710b that extends in a vertical direction from the underfill region DPR and covers at least a portion of the second upper package side S22 of the upper package P2.

For example, a height of the vertical extension portion 710b from the upper surface of the lower package P1 may be 30% to 80% of a height of the upper package P2 from the upper surface of the lower package P1. The height of the dam structure 450 from the upper surface of the lower package P1 may be within a range of 100 um to 500 um.

Thus, the upper package P2 may be mounted on the lower package P1 at a board level and then, the underfill process between the lower package P1 and the upper package P2 may be performed to complete the semiconductor package of FIG. 1 with secured reliability.

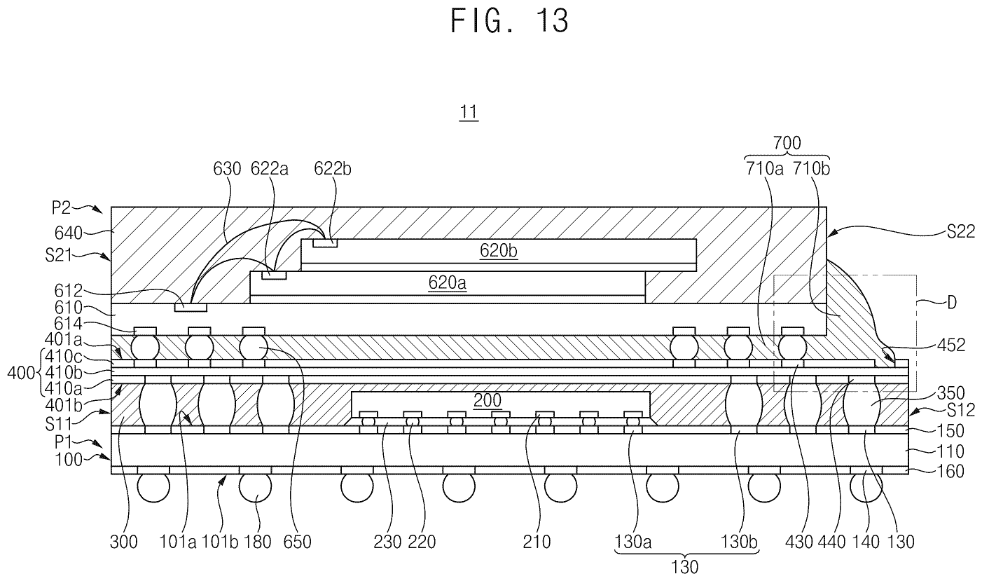

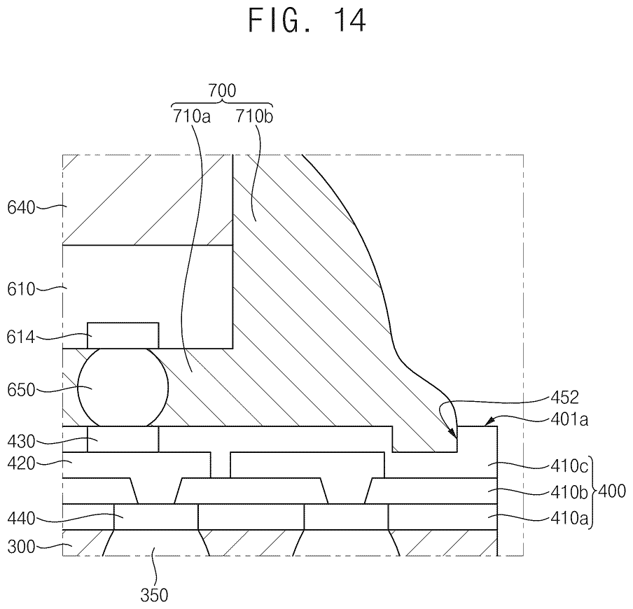

FIG. 13 is a cross-sectional view illustrating a semiconductor package in accordance with example embodiments. FIG. 14 is an enlarged cross-sectional view illustrating portion

‘D’ in FIG. 13. The semiconductor package may be substantially the same as the semiconductor package described with reference to FIGS. 1 to 3 except for a configuration of a receiving groove. Thus, same reference numerals may be used to refer to the same or like elements and any further repetitive explanation concerning the above elements will be omitted.

Referring to FIGS. 13 and 14, a lower package P1 of a semiconductor package 11 may include a receiving groove 452 that extends along a second lower package side S12 within an underfill region DPR on an upper surface 401a of the lower package P1. The receiving groove 452 may have a predetermined depth from the upper surface 401a. The receiving groove 452 may extend in a second direction (Y direction) to be adjacent to the second lower package side S12 within the underfill region DPR.

The receiving groove 452 may accommodate a portion of an underfill member 700. The receiving groove 452 may prevent the underfill member dispensed in the underfill region DPR on the upper surface 401a of an interposer 400 from flowing outward through the second lower package side S12.

As illustrated in FIG. 14, the interposer 400 as a redistribution wiring interposer may include first to third insulating layers 410a, 410b, and 410c sequentially stacked on a first molding member 300. The interposer 400 may include a lower connection pad 440 provided in the first insulating layer 410a and electrically connected to an end portion of a vertical conductive connector 350 exposed by a first molding member 300 and an upper bonding pad 430 provided in the third insulating layer 410c. The upper bonding pad 430 and the lower connection pad 440 may be electrically connected by a connection wiring 420.

The receiving groove 452 may be formed by performing a laser processing process on the plurality of insulating layers 410a, 410b, and 410c including the third insulating layer 410c. The receiving groove 452 may have a predetermined depth from the upper surface 401a of the third insulating layer 410c. For example, the depth may be in a range of 10 μm to 250 μm.

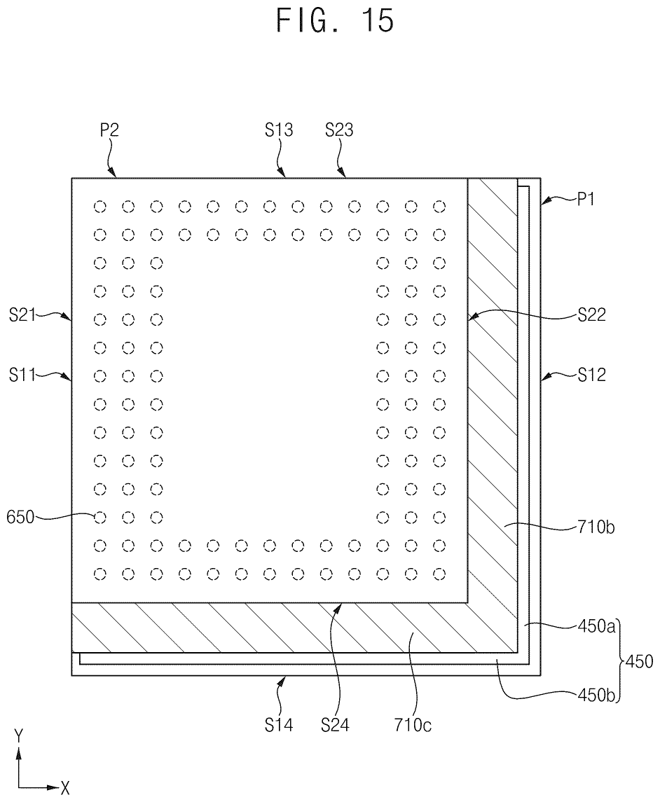

FIG. 15 is a plan view illustrating a semiconductor package in accordance with example embodiments. The semiconductor package is substantially the same as the semiconductor package described with reference to FIGS. 1 to 3 except for an arrangement of an upper package and configurations of an underfill member and a dam structure. Thus, same reference numerals may be used to refer to the same or like elements and any further repetitive explanation concerning the above elements will be omitted.

Referring to FIG. 15, an upper package P2 may be arranged asymmetrically on a lower package P1. A second upper package side S22 of the upper package P2 may be spaced apart from a second lower package side S12 of the lower package P1 by a predetermined distance, and a fourth upper package side S24 of the upper package P2 may be spaced apart from a fourth lower package side S14 of the lower package P1 by a predetermined distance to define an underfill region DPR on an upper surface of the lower package P1. A first upper package side S21 of the upper package P2 may be located on the same plane as a first lower package side S11 of the lower package P1 (i.e., the first upper package side S21 of the upper package P2 and the first lower package side S11 of the lower package P1 may be co-planar), and a third upper package side S23 of the upper package P2 may be located on the same plane as a third lower package side S13 of the lower package P1 (i.e., the third upper package side S23 of the upper package P2 and the third lower package side S13 of the lower package P1 may be co-planar). The underfill region DPR may be defined between the second upper package side S22 and the second lower package side S12 and between the fourth upper package side S24 and the second lower package side S14 on the upper surface 401a of the lower package P1.

In example embodiments, the lower package P1 may include a first vertical extension 710b that extends in a vertical direction from the underfill region DPR and covers at least a portion of the second upper package side S22 of the upper package P2, and a second vertical extension 710c that extends in the vertical direction from the underfill region DPR and covers at least a portion of the fourth upper package side S24 of the upper package P2. The first vertical extension 710b may be provided between the second upper package side S22 and the second lower package side S12 on the upper surface 401a of the lower package P1, and the second vertical extension 710c may be provided between the fourth upper package side S24 and the second lower package side S14 on the upper surface 401a of the lower package P1.

In addition, the lower package P1 may include a first dam structure 450a that extends in a second direction (Y direction) to be adjacent to the second lower package side S12 within the underfill region DPR on the upper surface of the lower package P1, and a second dam structure 450b that extends in a first direction (X direction) to be adjacent to the fourth lower package side S14 within the underfill region DPR. The first dam structure 450a may contact a portion of an outer surface of the first vertical extension 710b, and the second dam structure 450b may contact a portion of an outer surface of the second vertical extension 710c.

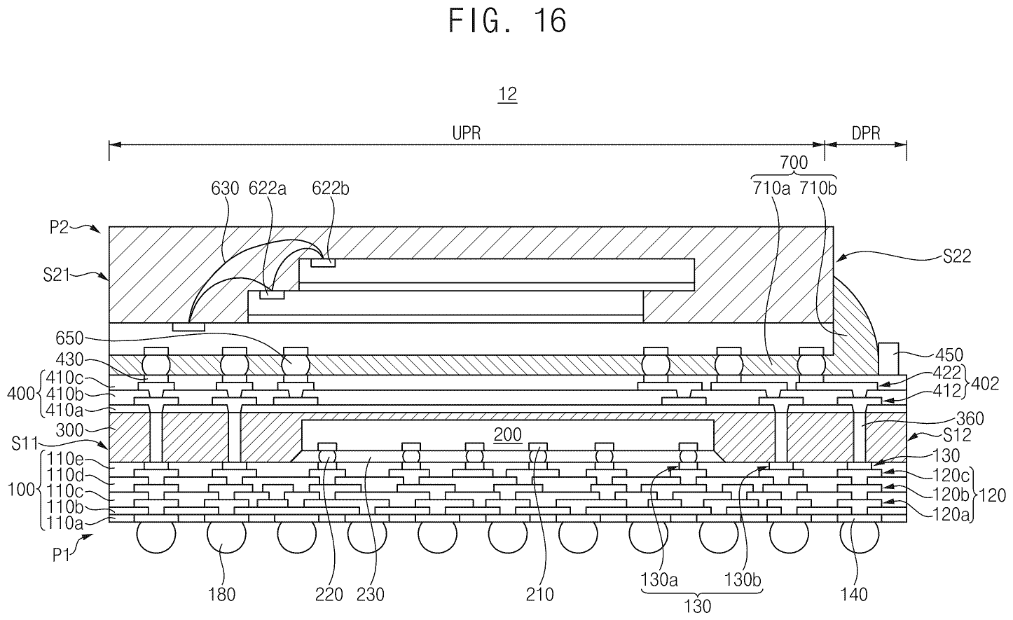

FIG. 16 is a cross-sectional view illustrating a semiconductor package in accordance with example embodiments. The semiconductor package is substantially the same as the semiconductor package described with reference to FIGS. 1 to 3 except for a configuration of a lower package. Thus, same reference numerals may be used to refer to the same or like elements and any further repetitive explanation concerning the above elements will be omitted.

Referring to FIG. 16, a semiconductor package 12 may include a lower package P1, an upper package P2 stacked on the lower package P1 using conductive connection members 650, and an underfill member 700 interposed between the lower package P1 and the upper package P2.

In example embodiments, the lower package P1 may include a fan out package. The lower package P1 may include a lower redistribution wiring layer 100, at least one first semiconductor chip 200 mounted on the lower redistribution wiring layer 100, vertical conductive pillars 360 disposed on the lower redistribution wiring layer 100 and electrically connected to the at least one first semiconductor chip, a first sealing member 300 covering the at least one first semiconductor chip 200 on the lower redistribution wiring layer 100 and exposing upper end portions of the vertical conductive pillars 360, and an upper redistribution wiring layer 400 on the first molding member 300 and electrically connected to the vertical conductive pillars 360.

The lower redistribution wiring layer 100 may be a front redistribution wiring layer (FRDL) of the fan out package. The lower redistribution wiring layer 100 may include first to fifth lower insulating layers 110a, 110b, 110c, 110d, and 110e and first redistribution wirings 120 stacked in at least two layers. The first redistribution wirings 120 may include first to third lower redistribution wirings 120a, 120b, and 120c that are vertically stacked.

Upper bonding pads 130 may be exposed from a lower surface of the lower redistribution wiring layer 100 (i.e., the upper bonding pads 130 may be exposed at a lower surface of the lower redistribution wiring layer 100). Lower bonding pads 140 may be exposed from a lower surface of the lower redistribution wiring layer 100. The upper bonding pads 130 may include first bonding pads 130a disposed in a chip mounting region and second bonding pads 130b disposed in a fan-out region surrounding the chip mounting region.

The semiconductor chip 200 may be disposed in the chip mounting region, which is a fan-in region of the lower redistribution wiring layer 100. The semiconductor chip 200 may be mounted on the upper surface of the lower redistribution wiring layer 100 using a flip chip bonding method. The semiconductor chip 200 may be disposed such that a front surface 202 on which chip pads 210 are formed, that is, an active surface, faces the lower redistribution wiring layer 100. The chip pads 210 of the semiconductor chip 200 may be electrically connected to the first redistribution wirings 102 of the lower redistribution wiring layer 100 through conductive bumps 220. The conductive bumps 220 may be respectively bonded to the first bonding pads 130a on the uppermost first redistribution wirings 120c. For example, the conductive bump 220 may include a micro bump (uBump).

The vertical conductive pillars 360 as vertical conductive structures may be respectively disposed on the second bonding pads 130b in the fan-out region of the lower redistribution wiring layer 100.

The first sealing member 300 may cover the semiconductor chip 200 and the plurality of vertical conductive pillars 360 on the upper surface of the lower redistribution wiring layer 100. The first sealing member 300 may expose the upper end portions of the vertical conductive pillars 360.

The upper redistribution wiring layer 400 may be disposed on the upper surface of the first sealing member 300. The upper redistribution wiring layer 400 may include stacked first to third upper insulating layers 410a, 410b, and 410c and second redistribution wirings 402 in the first to third upper insulating layers 410a, 410b, and 410c. The second redistribution wirings 402 may include first and second upper redistribution wirings 412 and 422. The upper bonding pads 430 may be respectively disposed on the second upper redistribution wirings 422 as the uppermost redistribution wirings.

The lower package P1 may have a rectangular shape with four sides when viewed in plan view. The lower package P1 may include a first lower package side S11 and a second lower package side S12 that extend in parallel directions and that are opposite to each other, as illustrated. The lower package P1 may have a first planar area.

The lower package P1 may include an upper package region UPR and an underfill region DPR on the upper surface of the upper redistribution wiring layer 400. Upper bonding pads 430 of the upper redistribution wiring layer 400 may be arranged in the upper package region UPR. One side portion of the upper package region UPR may overlap the first lower package side S11. The underfill region DPR may extend along the second lower package side S12 in one side of the upper package region UPR. One side portion of the underfill region DPR may overlap the second lower package side S12.

In example embodiments, the upper package P2 may be mounted on the lower package P1 via conductive connection members 650.

The upper package P2 may have a rectangular shape with four sides when viewed in plan view. The upper package P2 may include a first upper package side S21 and a second upper package side S21 that extend in parallel directions and that are opposite to each other, as illustrated. The upper package P2 may have a second planar area that is smaller than the first planar area of the lower package P1.

The upper package P2 may be arranged asymmetrically on the lower package P1. The upper package P2 may be disposed on the upper package region UPR of the lower package P1. The first upper package side S21 of the upper package P2 may be located on the same plane as the first lower package side S11 of the lower package P1 (i.e., the first upper package side S21 of the upper package P2 and the first lower package side S11 of the lower package P1 may be co-planar), and the second upper package side S22 may be spaced apart from the second lower package side S12 by a predetermined distance L1 such that the upper package P2 exposes the underfill region DPR on the upper surface of the lower package P1. A position of the center of the upper package P2 may be shifted in one direction with respect to the center of the lower package P1 to provide the underfill region DPR on the upper surface of the lower package P1 between the second upper package side S22 and the second lower package side S12.

In example embodiments, the underfill member 700 may include a horizontal extension portion 710a that extends in a horizontal direction from the underfill region DPR and fills a space between the lower package P1 and the upper package P2, and a vertical extension portion 710b that extends in a vertical direction from the underfill region DPR and covers at least a portion of the second upper package side S22 of the upper package P2.

Additionally, the lower package P1 may include a dam structure 450 that extends along the second lower package side S12 within the underfill region DPR on the upper surface of the upper redistribution wiring layer 400. The dam structure 450 may have a predetermined height from the upper surface of the upper redistribution wiring layer 400. The dam structure 450 may contact a portion of an outer surface of the underfill member 700. The dam structure 450 may prevent the underfill member dispensed in the underfill region DPR on the upper surface of the upper redistribution wiring layer 400 from flowing outward through the second lower package side S12.

Hereinafter, a method of manufacturing the semiconductor package of FIG. 16 will be described.

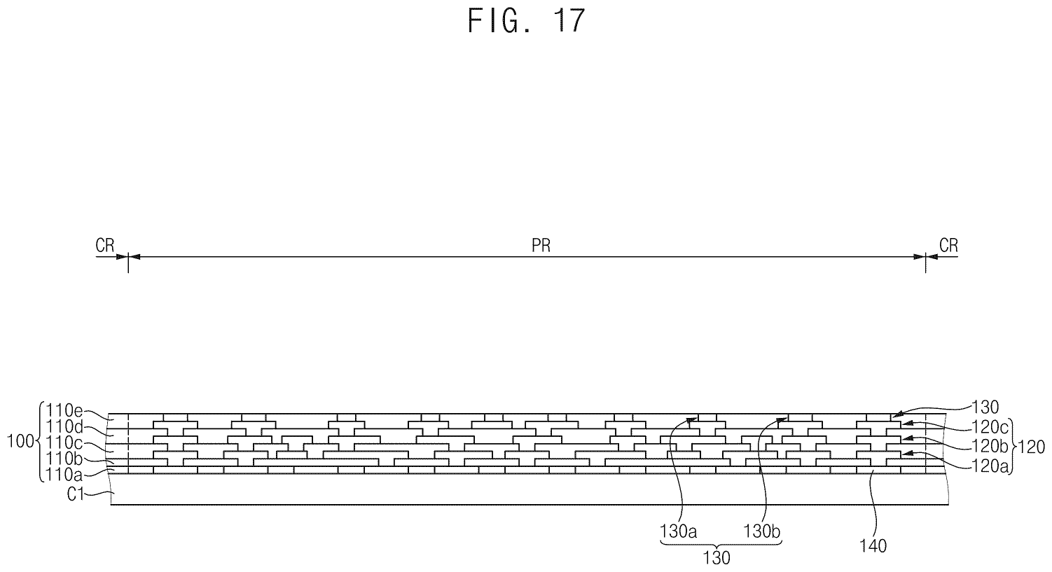

FIGS. 17 to 25 are views illustrating a method of manufacturing a semiconductor package in accordance with example embodiments.

Referring to FIG. 17, a lower redistribution wiring layer 100 having first redistribution wirings 120 may be formed on a carrier substrate C1.

In example embodiments, the carrier substrate C1 may include a wafer substrate as a base substrate on which a plurality of semiconductor chips are disposed on the lower redistribution wiring layer and a molding member is formed to cover them. The carrier substrate C1 may have a shape corresponding to the wafer on which a semiconductor process is performed. For example, the carrier substrate C1 may include a silicon substrate, a glass substrate, a non-metallic or metallic plate, etc.

The carrier substrate C1 may include a package region PR on which the semiconductor chip is mounted and a cutting region CR surrounding the package region PR. As will be described later, the lower redistribution wiring layer 100 and the molding member formed on the carrier substrate C1 may be cut along the cutting region CR that divides the plurality of package regions MR to be individualized.

In example embodiments, a first lower insulating layer 110a having lower bonding pads 140 formed therein may be formed on the carrier substrate C1. After forming a release film, a barrier metal layer, a seed layer, and the first lower insulating layer on the carrier substrate C1, the first lower insulating layer may be patterned to form openings that expose first bonding pad regions. Then, a plating process may be performed on the seed layer to form the lower bonding pads 140 in the openings.

For example, the first lower insulating layer 110a may include a polymer, a dielectric layer, etc. The first lower insulating layer 110a may include an insulating layer such as a photosensitive insulating material (PID) or ABF. The first lower insulating layer may be formed by a spin coating process, a vapor deposition process, or the like.

The lower bonding pad 140 may be a bump pad. The bump pad may include a solder pad or pillar pad. For example, the lower bonding pad may include copper (Cu), aluminum (Al), tin (Sn), nickel (Ni), gold (Au), platinum (Pt), or an alloy thereof.

Then, a second lower insulating layer 110b may be formed on the first lower insulating layer 110a to cover the lower bonding pads 140, and then the second lower insulating layer 110b may be patterned to form first openings that expose at least portions of the lower bonding pads 140 respectively.

Then, first lower redistribution wirings 120a may be formed on the second lower insulating layer 110b to be electrically connected to the lower bonding pads 140 through the first openings.

For example, the first lower redistribution wiring 120a may be formed by forming a seed layer on a portion of the second lower insulating layer 110b and in the first opening, patterning the seed layer, and performing an electrolytic plating process. Accordingly, at least a portion of the first lower redistribution wiring 120a may directly contact the lower bonding pad 140 through the first opening. For example, the first lower redistribution wiring may include copper (Cu), aluminum (Al), tin (Sn), nickel (Ni), gold (Au), platinum (Pt), or alloys thereof.

Similarly, a third lower insulating layer 110c may be formed on the second lower insulating layer 110b to cover the first lower redistribution wirings 120a, and the third lower insulating layer 110c may be patterned to form second openings that expose at least portions of the first lower redistribution wirings 120a. Then, second lower redistribution wirings 120b may be formed on the third lower insulating layer 110c to directly contact the first lower redistribution wirings 120a through the second openings.

Then, a fourth lower insulating layer 110d may be formed on the third lower insulating layer 110c to cover the second lower redistribution wirings 120b, and the fourth lower insulating layer 110d may be patterned to form third openings that expose at least portions of the second lower redistribution wirings 120b. Then, third lower redistribution wirings 120c may be formed on the fourth lower insulating layer 110d to directly contact the second lower redistribution wirings 120b through the third openings.

Then, a fifth lower insulating layer 110e may be formed on the fourth lower insulating layer 110d to cover the third lower redistribution wirings 120c.

Thus, the lower redistribution wiring layer 100 having the first to fifth lower insulating layers 110a, 110b, 110c, 110d, and 110e may be formed. The lower redistribution wiring layer 100 may be a front redistribution wiring layer (FRDL) of the fan out package. The lower redistribution wiring layer 100 may include the first redistribution wirings 120 stacked in at least two layers. The lower bonding pads 140 may be exposed from a lower surface of the lower redistribution wiring layer 100. The first redistribution wirings 120 may include the first to third lower redistribution wirings 120a, 120b, and 120c that are vertically stacked. For example, a thickness of the first redistribution wiring layer 100 may be within the range of 5μm to 50 μm.

Then, upper bonding pads 130 may be formed on the uppermost first redistribution wirings 120c on an upper surface of the lower redistribution wiring layer 100.

For example, the fifth lower insulating layer 110e may be patterned to form openings that respectively expose the third lower redistribution wirings 120c. The third lower redistribution wirings 120c exposed by the openings may be the uppermost redistribution wirings. A portion of the uppermost redistribution wiring may include a redistribution pad portion.

Then, the upper bonding pads 130 may be formed on the third lower redistribution wirings 120c exposed by the openings by a plating process. The upper bonding pads may include a metal material. The upper bonding pads may include a material the same as the third lower redistribution wiring 120c. The upper bonding pads may include copper (Cu). The upper bonding pads 130 may include first bonding pads 130a disposed in a middle region of the package region PR, that is, a chip mounting region, and second bonding pads 130b disposed in an edge region surrounding the chip mounting region.

Referring to FIG. 18, at least one semiconductor chip 200 may be mounted on the upper surface of the lower redistribution wiring layer 100, and vertical conductive pillars 360 may be formed around the semiconductor chip 200 on the upper surface of the lower redistribution wiring layer 100.

In example embodiments, a plurality of the vertical conductive pillars 360 may be formed on the second bonding pads 130b in the edge region of the lower redistribution wiring layer 100, that is, a fan-out region. A seed layer and a photoresist pattern may be sequentially formed on the lower redistribution wiring layer 100, and an electrolytic plating process may be performed to fill the openings of the photoresist pattern with a conductive material to form the vertical conductive pillars 360. For example, the vertical conductive pillar 360 may include copper (Cu). A lower end portion of the vertical conductive pillar 360 may be bonded to the second bonding pad 130b. Then, the photoresist pattern may be removed through a strip process.

Then, the semiconductor chip 200 may be disposed in the chip mounting region, which is a fan-in region of the lower redistribution wiring layer 100. The semiconductor chip 200 may be mounted on the upper surface of the lower redistribution wiring layer 100 using a flip chip bonding method. The semiconductor chip 200 may be disposed such that a front surface 202 on which chip pads 210 are formed, that is, an active surface, faces the lower redistribution wiring layer 100. The chip pads 210 of the semiconductor chip 200 may be electrically connected to the first redistribution wirings 102 of the lower redistribution wiring layer 100 through conductive bumps 220. The conductive bumps 220 may be respectively bonded to the first bonding pads 130a on the uppermost first redistribution wirings 120c. For example, the conductive bump 220 may include a micro bump (uBump).

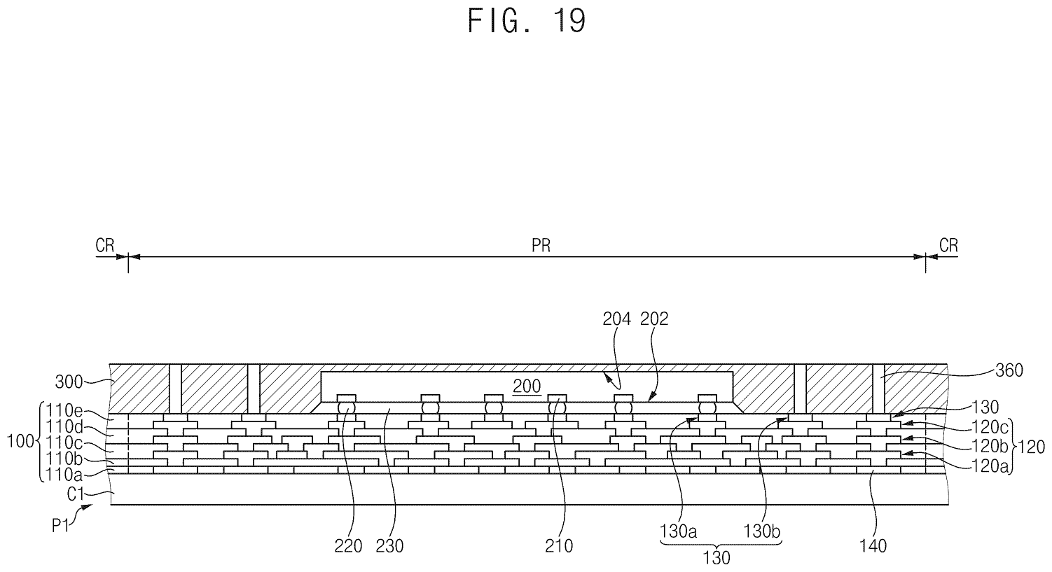

Referring to FIG. 19, a first sealing member 300 may be formed on the upper surface of the lower redistribution wiring layer 100 to cover the semiconductor chip 200 and the plurality of vertical conductive pillars 360. For example, the first sealing member 300 may include an epoxy mold compound (EMC). The first sealing member 300 may include a first sealing portion that covers a backside surface 204 of the semiconductor chip 200, that is, an upper surface, and a second sealing portion that covers the upper surface of the lower redistribution wiring layer 100 around the semiconductor chip 200. The first sealing member 300 may expose upper end portions of the vertical conductive pillars 360.

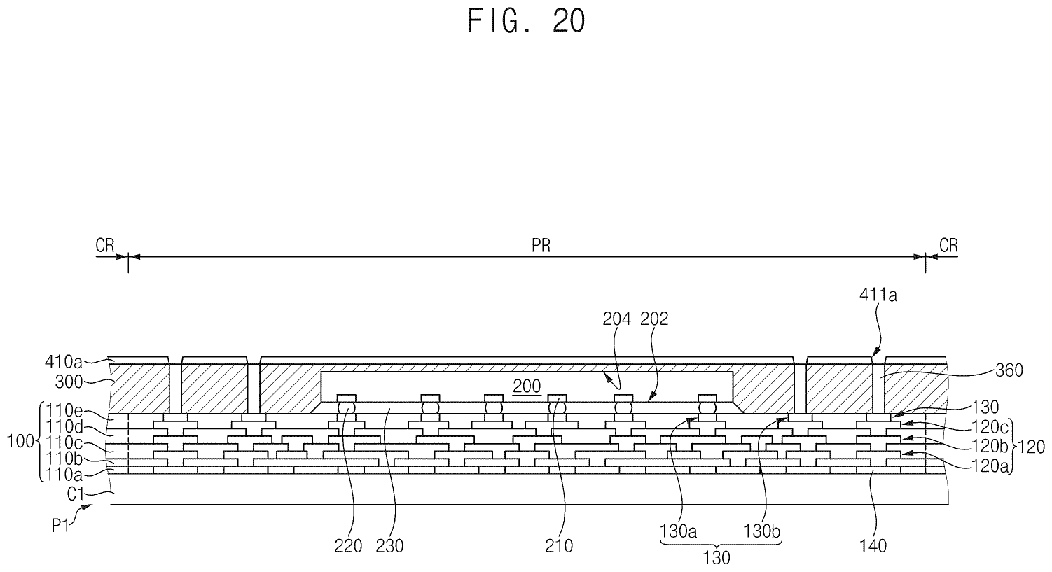

Referring to FIGS. 20 to 22, an upper redistribution wiring layer 400 having second redistribution wirings 402 electrically connected to the vertical conductive pillars 360 may be formed on the first sealing member 300.

As illustrated in FIG. 20, a first upper insulating layer 410a may be on the upper surface of the first sealing member 300, and the first upper insulating layer 410a may be patterned to form openings 411a that expose the upper end portions of the vertical conductive pillars 360 respectively. The first upper insulating layer 410a may include a polymer, a dielectric layer, etc. The first upper insulating layer 410a may be formed by a vapor deposition process, spin coating process, etc.

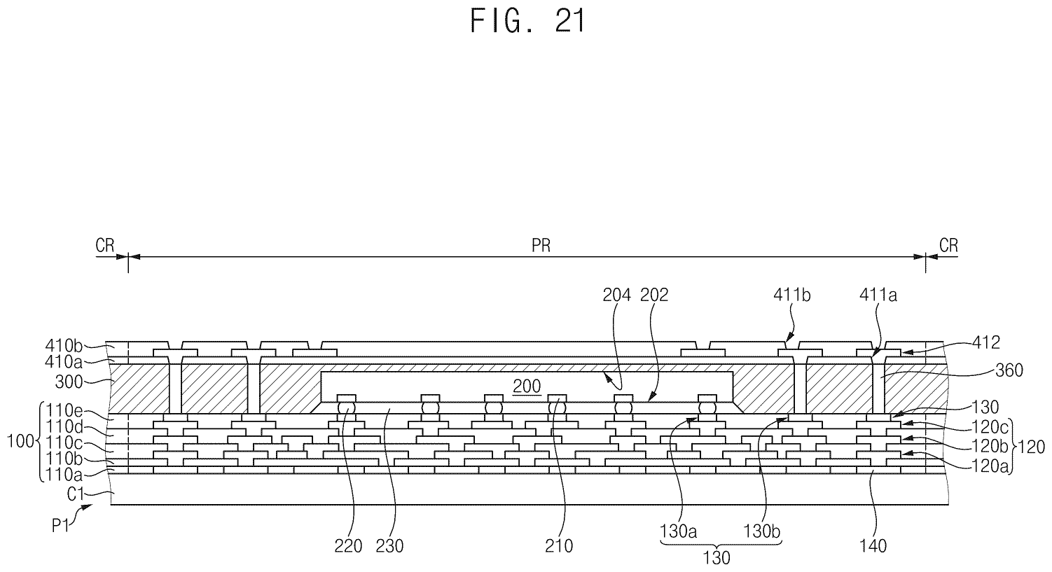

As illustrated in FIG. 21, a seed layer may be formed on the upper end portions of the vertical conductive pillars 360 exposed by the openings 411a and in the openings 411a, the seed layer may be patterned and an electrolytic plating process is performed to form first upper redistribution wirings 412. Accordingly, the first upper redistribution wirings 412 may be electrically connected to the vertical conductive pillars 360 through the openings 411a. The first upper redistribution wiring may include aluminum (Al), copper (Cu), tin (Sn), nickel (Ni), gold (Au), platinum (Pt), or alloys thereof.

Then, a second upper insulating layer 410b may be formed on the first upper insulating layer 410a, and the second upper insulating layer 410b may be patterned to form openings 411b that expose the first upper redistribution wirings 412.

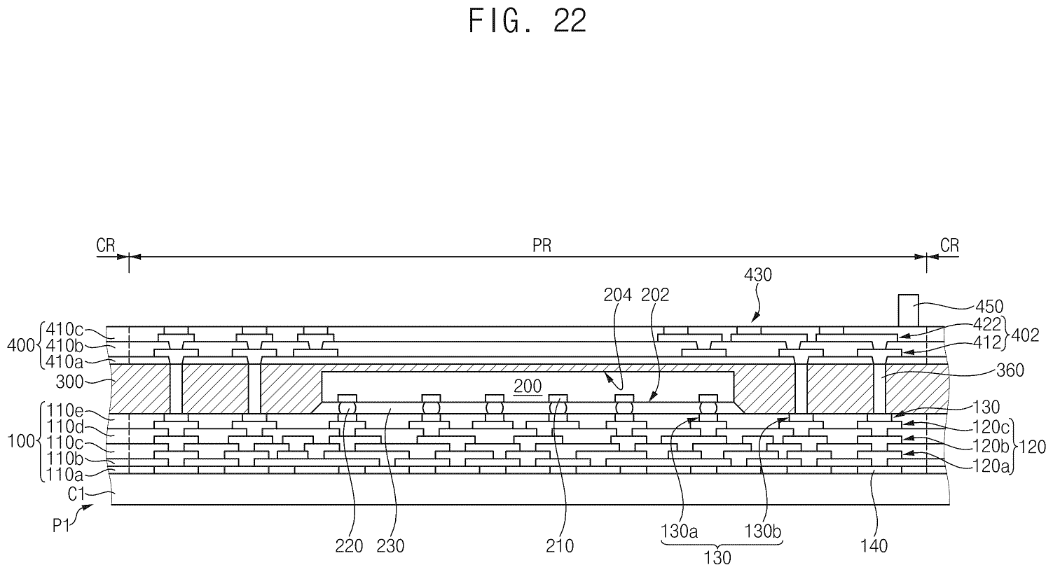

As illustrated in FIG. 22, second upper redistribution wirings 422 may be formed on the second upper insulating layer 410b to directly contact the first upper redistribution wirings 412 through the openings 411b.

Thus, the second redistribution wirings 402 may include the first upper redistribution wiring 412 and the second upper redistribution wiring 422 stacked in at least two layers. In this case, the first upper redistribution wiring 412 may correspond to the lowest redistribution wiring among the second redistribution wirings, and the second upper redistribution wiring 422 may correspond to the uppermost redistribution wiring among the second redistribution wirings.

Then, upper bonding pads 430 may be formed on the second upper redistribution wirings 422 as the uppermost redistribution wirings, and a third upper insulating layer 410c may be formed on the second upper insulating layer 410b to expose at least portions of the upper bonding pads 422. The third upper insulating layer 410c may function as a passivation layer.

Thus, the upper redistribution wiring layer 400 having the second redistribution wirings 402 as a backside redistribution wiring layer (BRDL) may be formed on the first sealing member 300. The upper redistribution wiring layer 400 includes the stacked first to third upper insulating layers 410a, 410b, and 410c and the second redistribution wirings 402 in the first to third upper insulating layers 410a, 410b, and 410c. The second redistribution wirings 402 may include the first and second upper redistribution wirings 412 and 422.

It will be understood that the number, size, and arrangement of the upper insulating layers and the upper redistribution wirings of the upper redistribution wiring layer are provided as examples, and the present inventive concept is not limited thereto.

Then, a dam structure 450 may be formed on the upper surface of the upper redistribution wiring layer 400 and may extend along one side of the cutting region CR. The dam structure 450 may have a predetermined height from the upper surface of the upper redistribution wiring layer 400. As will be described later, the dam structure 450 may prevent an underfill member dispensed on the upper surface of the upper redistribution wiring layer 400 from flowing out.

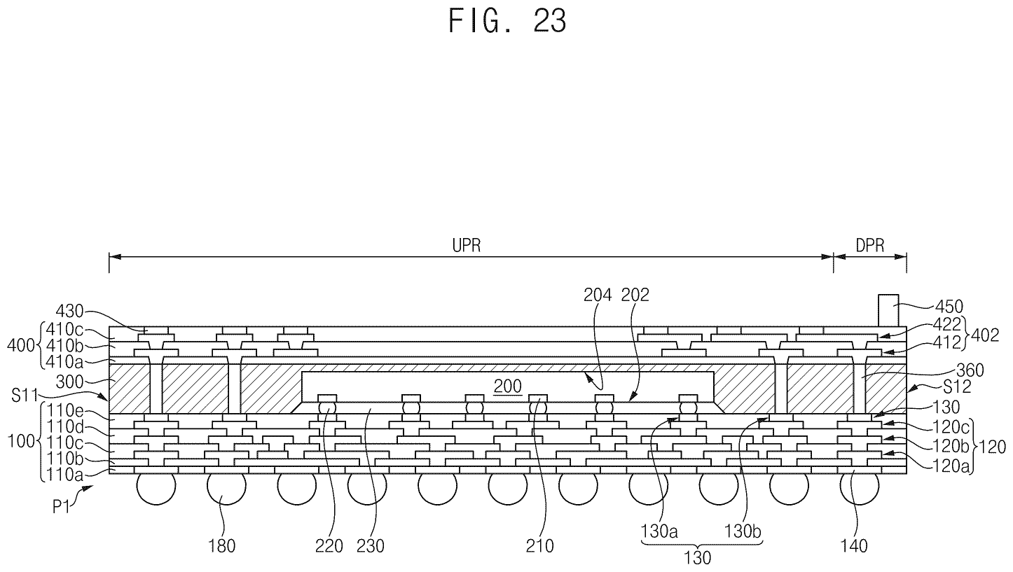

Referring to FIG. 23, the carrier substrate C1 may be removed, and external connection members 180 may be formed on an outer surface of the lower redistribution wiring layer 100, that is, on the lower bonding pads 140 on a lower surface of the lower redistribution wiring layer. Then, through a sawing process, the lower redistribution wiring layers 100 may be separated to form individual lower packages P1.

In example embodiments, solder balls may be disposed as the external connection members on the lower substrate pads 140 on the lower surface of the lower redistribution wiring layer 100. Then, the lower redistribution wiring layer 100 may be cut along the cutting region CR that dividing the plurality of package regions PR by the sawing process, to be individualized into the lower packages P1.

The lower package P1 may include the lower redistribution wiring layer 100, the at least one first semiconductor chip 200 mounted on the lower redistribution wiring layer 100, the vertical conductive pillars 360 on the lower redistribution wiring layer 100 and electrically connected to the at least one first semiconductor chip 200, and the first sealing member 300 covering the at least one first semiconductor chip 200 on the lower redistribution wiring layer 100 and exposing upper end portions of the vertical conductive pillars 360, and the upper redistribution wiring layer 400 electrically connected to the vertical conductive pillars 360 on the first molding member 300.

The lower package P1 may have a rectangular shape with four sides when viewed in plan view. The lower package P1 may include a first lower package side S11 and a second lower package side S12 that extend in parallel directions and that are opposite each other, as illustrated. The lower package P1 may have a first planar area.

The lower package P1 may include an upper package region UPR and an underfill region DPR on the upper surface of the upper redistribution wiring layer 400. The upper bonding pads 430 of the upper redistribution wiring layer 400 may be arranged in the upper package region UPR. One side portion of the upper package region UPR may overlap the first lower package side S11. The underfill region DPR may extend along the second lower package side S12 in one side of the upper package region UPR. One side portion of the underfill region DPR may overlap the second lower package side S12.

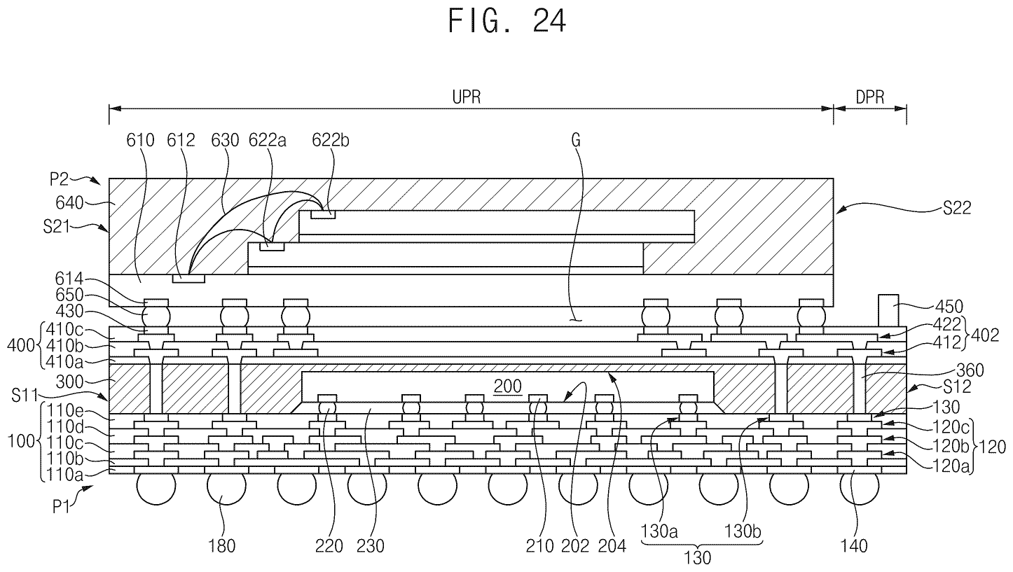

Referring to FIG. 24, the upper package P2 may be stacked on the lower package P1 via conductive connection members 650.

In example embodiments, solder balls as the conductive connection members may be respectively formed on lower substrate pads 614 of a lower surface of a package substrate 610 of the upper package P2 by a solder ball attach process. Then, the upper package P2 may be mounted on the lower package P1 using the conductive connection members.

The conductive connection members 650 may be interposed between the lower package P1 and the upper package P2 to electrically connect them. A gap G may be formed between the upper package P2 and the lower package P1 by the conductive connection members 650. The conductive connection members 650 formed on the lower substrate pads 614 of the second package substrate 610 of the lower package P1 may be bonded to the upper bonding pads 430 arranged in the upper package region UPR of the upper redistribution wiring layer 400.

The upper package P2 may have a rectangular shape with four sides when viewed in plan view. The upper package P2 may include a first upper package side S21 and a second upper package side S21 that extend in parallel directions and that are opposite each other, as illustrated. The upper package P2 may have a second planar area that is smaller than the first planar area.

The upper package P2 may be disposed on the upper package region UPR of the lower package P1. The first upper package side S21 of the upper package P2 may be located on the same plane as the first lower package side S11 of the lower package P1, and the second upper package side S22 may be spaced apart from the second lower package side S12 by a predetermined distance L1 such that the upper package P2 exposes the underfill region DPR on the upper surface of the lower package P1. A position of the center of the upper package P2 may be shifted in one direction with respect to the center of the lower package P1 to provide the underfill region DPR on the upper surface of the lower package P1 between the second upper package side S22 and the second lower package side S12.

In this case, the dam structure 450 may extend in one direction to be adjacent to the second lower package side S12 within the underfill region DPR on the upper surface of the lower package P1.

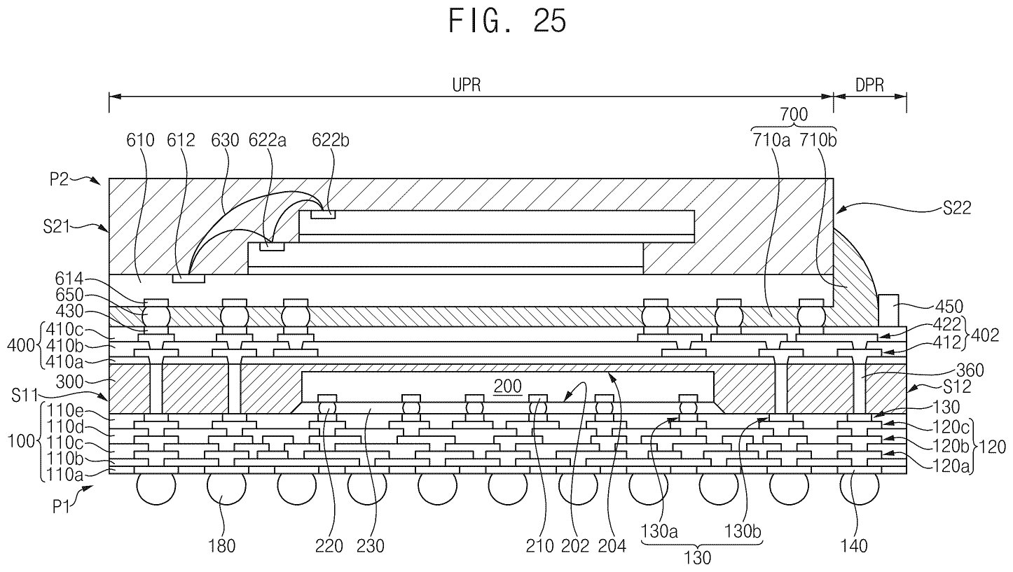

Referring to FIG. 25, processes the same as or similar to the processes described with reference to FIGS. 11 and 12 may be performed to form an underfill member 700 between the lower package P1 and the upper package P2.

In example embodiments, the underfill member 700 may include a horizontal extension portion 710a that extends in a horizontal direction from the underfill region DPR and fills the space between the lower package P1 and the upper package P2, and a vertical extension portion 710b that extends in a vertical direction from the underfill region DPR and covers at least a portion of the second upper package side S22 of the upper package P2.

For example, a height of the vertical extension portion 710b from the upper surface of the lower package P1 may be 30% to 80% of a height of the upper package P2 from the upper surface of the lower package P1. A height of the dam structure 450 from the upper surface of the lower package P1 may be within a range of 100 μm to 500 μm.

Accordingly, the upper package P2 may be mounted on the lower package P1 at a board level and an underfill process may be performed between the lower package P1 and the upper package P2 to complete the semiconductor package of FIG. 16 having improved reliability.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a lower package having opposite first and second lower package sides that extend in a first direction;
an upper package stacked on the lower package by conductive connection members, the upper package having opposite first and second upper package sides that extend in the first direction, wherein the first upper package side and the first lower package side are co-planar, and the second upper package side is spaced apart from the second lower package side by a predetermined distance to define an underfill region on an upper surface of the lower package; and
an underfill member extending from the underfill region on the upper surface of the lower package to fill a space between the lower package and the upper package.

2. The semiconductor package of claim 1, wherein the underfill member comprises a first extension portion that covers at least a portion of the second upper package side of the upper package.

3. The semiconductor package of claim 1, wherein the predetermined distance is at least 0.5 mm.

4. The semiconductor package of claim 1, wherein the lower package comprises a dam structure that extends along the second lower package side within the underfill region on the upper surface of the lower package and has a predetermined height above the upper surface of the lower package.

5. The semiconductor package of claim 1, wherein the lower package comprises a receiving groove that extends along the second lower package side within the underfill region on the upper surface of the lower package and has a predetermined depth below the upper surface of the lower package.

6. The semiconductor package of claim 1, wherein the lower package has opposite third and fourth lower package sides that extend in a second direction perpendicular to the first direction,
wherein the upper package has opposite third and fourth upper package sides that extend in the second direction, and
wherein the third upper package side and the third lower package side of the lower package are co-planar, and the fourth upper package side is spaced apart from the fourth lower package side by a predetermined distance to define a second underfill region on the upper surface of the lower package.

7. The semiconductor package of claim 1, wherein the lower package comprises:
a first package substrate;
at least one first semiconductor chip mounted on the first package substrate;
conductive connectors on the first package substrate and electrically connected to the at least one first semiconductor chip;
a first sealing member on the first package substrate and covering the at least one first semiconductor chip, wherein end portions of the conductive connectors are exposed through the first sealing member; and
an interposer electrically connected to the conductive connectors on the first sealing member, wherein the interposer comprises upper connection pads, and
wherein each of the conductive connection members is on a respective one of the upper connection pads of the interposer.

8. The semiconductor package of claim 7, wherein the at least one first semiconductor chip is arranged such that a front surface on which first chip pads are formed faces the first package substrate.

9. The semiconductor package of claim 7, wherein the first package substrate comprises a lower redistribution wiring layer having lower redistribution wirings, and wherein the interposer comprises an upper redistribution wiring layer having upper redistribution wirings electrically connected to the conductive connectors.

10. The semiconductor package of claim 1, wherein the upper package comprises:
a second package substrate;
at least one second semiconductor chip mounted on the second package substrate; and
a second sealing member on the second package substrate and covering the at least one second semiconductor chip.

11. A semiconductor package, comprising:
a lower package having a first planar area and opposite first and second lower package sides that extend in a first direction;
an upper package stacked on the lower package by conductive connection members, the upper package having a second planar area smaller than the first planar area, the upper package having opposite first and second upper package sides that extend in the first direction,
wherein a center of the lower package is offset relative to a center of the upper package, thereby defining an underfill region on an upper surface of the lower package between the second upper package side and the second lower package side; and
an underfill member extending from the underfill region on the upper surface of the lower package to fill a space between the lower package and the upper package.

12. The semiconductor package of claim 11, wherein the first upper package side and the first lower package side are co-planar.

13. The semiconductor package of claim 11, wherein the underfill member comprises a first extension portion that covers at least a portion of the second upper package side of the upper package.

14. The semiconductor package of claim 11, wherein the second upper package side is spaced apart from the second lower package side by at least 0.5 mm.

15. The semiconductor package of claim 11, wherein the lower package comprises a dam structure that extends along the second lower package side within the underfill region on the upper surface of the lower package and has a predetermined height from the upper surface of the lower package.

16. The semiconductor package of claim 11, wherein the lower package comprises a receiving groove that extends along the second lower package side within the underfill region on the upper surface of the lower package and has a predetermined depth below the upper surface of the lower package.

17. The semiconductor package of claim 11, wherein the lower package has opposite third and fourth lower package sides that extend in a second direction transverse to the first direction,
wherein the upper package has opposite third and fourth upper package sides that extend in the second direction, and
wherein the third upper package side and the third lower package side are co-planar, and the fourth upper package side is spaced apart from the fourth lower package side by a predetermined distance to define a second underfill region on the upper surface of the lower package.

18. The semiconductor package of claim 11, wherein the lower package comprises:
a first package substrate;
at least one first semiconductor chip mounted on the first package substrate;
conductive connectors on the first package substrate and electrically connected to the at least one first semiconductor chip;
a first sealing member on the first package substrate and covering the at least one first semiconductor chip, wherein end portions of the conductive connectors are exposed through the first sealing member; and
an interposer electrically connected to the conductive connectors on the first sealing member and having upper connection pads, and
wherein each of the conductive connection members are on a respective one of the upper connection pads of the interposer.

19. The semiconductor package of claim 18, wherein the first package substrate comprises a lower redistribution wiring layer having lower redistribution wirings, and wherein the interposer comprises an upper redistribution wiring layer having upper redistribution wirings electrically connected to the conductive connectors.

20. A semiconductor package, comprising:
a lower package having a first planar area and opposite first and second lower package sides that extend in a first direction;
an upper package having a second planar area smaller than the first planar area, the upper package having opposite first and second upper package sides that extend in the first direction, wherein a center of the lower package is offset relative to a center of the upper package to define an underfill region on an upper surface of the lower package between the second upper package side and the second lower package side; and
an underfill member extending from the underfill region on the upper surface of the lower package and filling a space between the lower package and the upper package,
wherein the lower package comprises:
a first package substrate;
at least one first semiconductor chip mounted on the first package substrate;
conductive connectors on the first package substrate and electrically connected to the at least one first semiconductor chip;
a first sealing member on the first package substrate and covering the at least one first semiconductor chip, wherein end portions of the conductive connectors are exposed through the first sealing member; and
an interposer electrically connected to the conductive connectors on the first sealing member and having upper connection pads,
wherein each od the conductive connection members is on a respective one of the upper connection pads of the interposer, and
wherein the first upper package side and the first lower package side are co-planar.
